(19) United States
(12) Patent Application Publication
(10) Pub. No.: US 2010/0108893 A1
(43) Pub. Date: May 6, 2010

(54) Devices and Methods for Ultra Thin Photodiode Arrays on Bonded Supports

(75) Inventors: Frederick A. Flitsch, New Windsor, NY (US); Alexander O. Goushcha, Aliso Viejo, CA (US)

Correspondence Address: BLAKELY SOKOLOFF TAYLOR & ZAFMAN LLP, 1279 OAKMEAD PARKWAY, SUNNYVALE, CA, 94085-4040, US

(73) Assignee: ARRAY OPTRONIX, INC., Costa Mesa, CA (US)

(21) Appl. No.: 12/606,012

(22) Filed: Oct. 26, 2009

Related U.S. Application Data
(60) Provisional application No. 61/111,110, filed on Nov. 4, 2008.

(51) Int. Cl. G01T 1/20; H01L 31/103; H01L 27/146; H01L 31/18

(52) U.S. Cl. 250/361 R; 257/461; 257/443; 257/446; 438/80; 257/E31.089; 257/E31.057; 257/E27.14; 257/E27.133

(57) ABSTRACT

Ultra thin photodiode array structures and fabrication methods are disclosed. The back illuminated or front illuminated photodiode arrays have the active portion fabricated in a semiconductor layer which may be bonded to a supporting substrate layer. The active portion of semiconductor layer may comprise epitaxially grown layer. The isolation regions between pixels of an array may span the epitaxial layer and a semiconductor layer. Electrical contacts to the diodes are made through the bonded substrate or a portion of active layer. Methods of fabrication include steps to form a photodiode array of this type as well as steps to bond this array to supporting substrates. In some embodiments, supporting substrates are temporarily bonded for support of the methods of processing.

### CROSS-REFERENCE TO RELATED APPLICATIONS

This application claims the benefit of U.S. Provisional Patent Application No. 61/111,110, filed Nov. 4, 2008, entitled “Devices and Methods for Ultra Thin Back-Illuminated Photodiode Arrays on Bonded Supports”.

### FIELD OF THE INVENTION

The present invention relates to semiconductor photodiodes, and in particular, to the structures of high performance, back-illuminated or front illuminated photodiode arrays and the methods of fabricating such structures particularly for thin embodiments of the active element and isolation features.

### BACKGROUND OF THE INVENTION

Conventional photodiode array structures are based on either front illuminated or back illuminated technologies. The semiconductor substrate may be either n-type or p-type material, with opposite conductivity type diffused regions therein. This creates a p-on-n or n-on-p structure, respectively. The Anode and Cathode metal pads that provide interconnects to downstream electronics may be placed either on different surfaces of the array or special structural features may be designed to provide pads for each of the two electrodes on the same surface of the array. The blanket-type implantation of the back surface of the die of the same conductivity type as the semiconductor substrate improves both the charge collection efficiency and DC/AC electrical performance of the devices.

Each of the two approaches—the front illuminated and back illuminated structures—has its own advantages and disadvantages. For example, traditional front illuminated structures with anode and cathode pads on different surfaces of the semiconductor substrate allow building high performance photodiodes and photodiode arrays, but impose severe constraints on the metal run width. Those constraints limit a design of the front illuminating photodiode array to the use of either a smaller number of elements, or larger gaps between adjacent elements. On the other hand, placing anode and cathode pads on the same surface of the semiconductor substrate may require through vias to provide contacts to the diffusion arranged close its one surface and to bring signals to the other surface, which generally deteriorate mechanical integrity of the array.

Back illuminated structures reported recently by several companies take advantage of bumping technology to electrically connect elements of the array to an external substrate or PC board using the contacts (bumps or studs) on the front surface of the structure. By utilizing solder or stud bump technology, the metal interconnects, which usually reside on top of the active surface between the adjacent elements openings, may be moved to the substrate or PC board upon which the chip is mounted. Such an approach allows minimizing the gaps between adjacent elements of the array, at the same time allowing a virtually unlimited total number of elements. However, several drawbacks of the previously reported back illuminated structures limit their application:

1) First, these structures are usually fabricated using relatively thick Si wafers (>50 μm) and the resistivity of the material has to be high enough (>500 Ohm-cm) to deplete as much as possible volume at zero bias, which is required for many applications;
2) Second, the application of a high resistivity material usually diminishes the photodiode performance with respect to the leakage current and shunt resistance;
3) Third, if a high resistivity material is not used, then the time response may be very long (micro seconds or even longer) because the time response would be determined by the carriers' diffusion rather than their drift in the depleted structures;
4) Fourth, a majority of the designs provide either little or no structural features that isolate adjacent cells from each other within the entire thickness of the device, which results in relatively high cross-talk, especially at zero bias;

Summarizing, such parameters as the leakage current, shunt resistance, cross-talk, spectral sensitivity, and temporal response are of main concern for the prior art of back illuminated structures. Additionally, the handling of thin wafers (<150 μm thickness) in the wafer fabrication process is a matter of great concern by itself, and would become increasingly important with the further decrease of the wafer thickness. It would be desirable to develop devices that afford the advantages of a thin device area while not requiring difficult processing in standard fabrication facilities.

### BRIEF DESCRIPTION OF THE DRAWINGS

The accompanying drawings, that are incorporated in and constitute a part of this specification, illustrate several embodiments of the invention and, together with the description, serve to explain the principles of the preferred embodiments of the invention:

FIG. 1 is an example of a partially processed device in accord with the embodiments of the invention where the initial deposition of dopants is made to form the p/n junctions and isolating structures.

FIG. 2 is an exemplary depiction of a partially processed device of the invention where the photosensitive portions therein are in an epitaxial semiconductor region.

FIG. 3 is an exemplary depiction of further processing of the device of the type in FIG. 2 whereas a bonded handling substrate has been affixed thereon.

FIG. 4 is an exemplary depiction of further processing of the device of the type in FIG. 3 where the original semiconductor substrate portion has been made ultrathin.

FIG. 5 is an exemplary depiction of further processing of the device of the type in FIG. 4 where a substrate has been bonded onto the thinned portion of the device and provides the material through which contact features to the active regions of the device are formed.

FIG. 6 is an exemplary depiction of further processing of the device of the type in FIG. 5 where a second handling substrate has been bonded to support removal of a first bonded handling substrate.

FIG. 7 is an exemplary depiction of further processing of the device of the type in FIG. 6 where the first handling substrate has been removed.

FIG. 8 is an exemplary depiction of an ultrathin, backside illuminated photodiode device with isolated pixels manufactured on semiconductor substrate with grown epitaxial layer and support substrate.

FIG. 9 is an example of the photodiode device of the type shown in FIG. 8 but with overlapping front- and backside isolation diffusion regions between active elements of the array.

FIG. 10 is another example of an ultrathin, backside illuminated photodiode device manufactured using a grown epitaxial semiconductor layer on top of the semiconductor-on-insulator substrate. The isolation features were made with dopants diffused from the opposite sides of the semiconductor layer.

FIG. 11 is another example of an ultrathin, backside illuminated photodiode device manufactured using grown epitaxial semiconductor layer on top of the semiconductor-on-insulator substrate. The isolation features were made with a combination of dopant diffusion from one side and through vias (trenches) from the opposite sides of the semiconductor layer.

FIG. 12 is another example of an ultrathin, backside illuminated photodiode device manufactured using grown epitaxial semiconductor layer on top of the semiconductor-on-insulator substrate. The isolation features were made with through vias (trenches) spanning the whole active region thickness from the light impinging side of the device.

FIG. 13 is another example of an ultrathin, backside illuminated photodiode device manufactured using grown epitaxial semiconductor layer on top of the semiconductor-on-insulator substrate. The isolation features were made with through vias (trenches) spanning the whole active region thickness, while the contact to the blanket diffusion of the light impinging side was made with a small number of through vias connecting both sides of the device.

FIG. 14 is another example of an ultrathin, backside illuminated photodiode device manufactured using grown epitaxial semiconductor layer on top of the semiconductor-on-insulator substrate. The structure is similar to that of FIG. 12 but with a very low thermal budget and thin starting active layer thickness.

FIG. 15 is another example of an ultrathin, backside illuminated photodiode device manufactured using grown epitaxial semiconductor layer on top of the semiconductor-on-insulator substrate. The structure exemplifies extremely thin starting semiconductor layer thickness, several epitaxial grown layers, and contains embedded devices in deeply buried epitaxial layers.

FIG. 16 is an exemplary depiction of another type of ultrathin, backside illuminated photodiode device built using bulk semiconductor substrate and vias through this substrate to contact doped regions of semiconductor from the side opposite to the light impinging side.

FIG. 17 is an exemplary depiction of another type of ultrathin, backside illuminated photodiode device with isolation diffusion enclosing each element and built using a bulk semiconductor wafer bonded to a support substrate.

FIG. 18 is an exemplary depiction of another type of ultrathin, backside illuminated photodiode device with isolation diffusion enclosing each element, bonded to a support substrate, and with vertical vias provided in a support substrate to contact the doped semiconductor regions.

FIG. 19 is an exemplary depiction of the ultrathin, backside illuminated photodiode device of the type shown in FIG. 9 but with isolation between pixels made using through vias (trenches).

FIG. 20 is an exemplary depiction of another type of ultrathin, backside illuminated photo-sensitive device comprising photodetector structure with internal amplification having isolation diffusion that encloses each element, bonded to a support substrate, and with vertical vias provided in a support substrate to contact the doped semiconductor regions.

FIG. 21 exemplifies an ultrathin, front illuminated photodiode device bonded to a support substrate and built using semiconductor epitaxial layer growth and isolating diffusion structures.

FIG. 22 is an exemplary depiction of the light entering surface of the photodiode array showing an exemplary rectangular shape of each light sensitive element.

FIG. 23 is a cross-sectional view of a photodiode shown in FIG. 2, showing abutting of the second conductivity type region with isolating regions of the first conductivity type; The cross-section is made along the surface of epitaxial layer growth.

FIG. 24 depicts an example of a detector module of an imaging system using a photodiode array of the present invention.

FIG. 25 is another example of the photosensitive device with multiple epitaxial layers, multiple doped regions within epitaxial layers, and multiple vias contacting different doped regions of a semiconductor.

The accompanying drawings, that are incorporated in and constitute a part of this specification, illustrate several embodiments of the invention and, together with the description, serve to explain the principles of the invention.

### DETAILED DESCRIPTION OF PREFERRED EMBODIMENTS

Accordingly, the first set of embodiments of the present invention provides ultra thin backside illuminated photosensitive devices that may employ standard semiconductor processing equipment. The devices of these embodiments are one-dimensional or two-dimensional arrays of photodiodes, each including the first semiconductor layer having the first and second surfaces and the second semiconductor layer bonded, deposited, or grown on the second surface of the first semiconductor layer. Therefore, the second semiconductor layer has the first surface in contact with the first semiconductor layer and the second surface.

The anode/cathode of each photodiode is formed by the first doping regions extending from the first surface of the first semiconductor layer through the whole thickness of the first semiconductor layer and inside the second semiconductor layer. This doping does not reach the second surface of the second semiconductor layer. The isolating regions penetrate through the first and second semiconductor layers and may reach the first surface of the first semiconductor layer and the second surface of the second semiconductor layer. The isolating regions form a rectangular or other shape cell on the first surface of the first semiconductor layer, each cell encloses the anode/cathode region of a single photodiode of the array. The isolation regions may be created by trenches or through vias, backfilled with standard filler. Alternatively, these isolation regions may be formed by the second doping regions, or a combination of trenches with the second doping regions.

In the former case (doping regions only), the second doping regions extend from the first surface of the first semiconductor layer through the bonding surfaces of the two semiconductor layers reaching the second surface of the second semiconductor layer. In the latter case (combination of doping regions and trenches), the second doping regions may extend from the first surface of the first semiconductor layer through the bonding surfaces of the two semiconductor layers and stop inside the bulk of the second semiconductor layer, not reaching the second surface of the second semiconductor layer; The isolation is completed in this case by trenches extending from the second surface of the second semiconductor layer inside its bulk and possibly touching the second doping regions.

The sidewalls of the trenches may be doped to comprise the portions of the second doping regions. In all cases, the second doping regions concentration may not necessarily be uniform along the path connecting the surfaces of the two semiconductor layers. Moreover, they may have gaps along this path, located inside the second semiconductor layer, with a very low or nonexistent second doping concentration. The third doping region is located proximate to the second surface of the second semiconductor layer and forms a common cathode/anode of a photodiode array. The second surface of the second semiconductor layer has a passivation layer. The first surface of the first semiconductor layer is attached to the support substrate using one or more intermediate adhesion, etch-stopping, and/or isolation layers.

The through vias are made in these support substrate and intermediate layers to open the first and second doping regions on the surface of the first semiconductor layer. There could be at least one through via per cell of a photodiode array reaching the first doping region of each photodiode. There could be at least one through via per array reaching the second doping region. Inside openings, the regions of the first semiconductor layer proximate to its first surface are covered or enriched with silicide or other known in the industry material to provide good Ohmic contact to the semiconductor areas.

The vias are used to create conductive paths with metal or other highly conductive material from the surface of the support substrate to the first and second doping areas. The vias may be backfilled with oxide, polysilicon, or other standard filler and the contact pads may be deposited on the top completing the structure of the backlit photodiode array. Alternatively, the metal that contacts the semiconductor doping regions may be patterned to form the contact pads.

The second set of embodiments of the present invention comprises the methods to manufacture backlit photodiode arrays bonded to the support substrate in accord with the first set of embodiments described in the above paragraphs.

The third set of embodiments of the present invention provides ultra thin front illuminated photosensitive device and array structures that may employ standard semiconductor processing equipment. The devices of these embodiments are one dimensional or two dimensional arrays of photodiodes, each having two semiconductor layers and many structural features similar or identical to the previous set of embodiments. However, the main feature of this set of embodiments that distinguishes it from the previous set is that the anode/cathode is formed on the second (top) surface of the second semiconductor layer, which results in the anode/cathode region formed proximate to the very top of the finished device structure. Accordingly, the through vias may be required in the top semiconductor layers to contact these anode/cathode regions and to bring signals to the bottom of the structure. Also, no vias through the top semiconductor layers may be required to contact the isolation regions.

The forth set of embodiments of the present invention comprises methods to manufacture the front-illuminated photodiode array bonded to the support substrate in accord with the third set of embodiments described in the above paragraphs.

The fifth set of embodiments of the present invention comprises an alternative version of ultra thin backside illuminated photosensitive devices that may employ standard semiconductor processing equipment. The devices of these embodiment types are one-dimensional or two-dimensional arrays of photodiodes, each including a single semiconductor layer having the first and second surfaces. The anode/cathode of each photodiode of the array is formed by the first doping regions extending from the first surface of the semiconductor layer inside the bulk of this second semiconductor layer.

The first doping region may not reach the second surface of the semiconductor layer. The isolating regions penetrate through the semiconductor layer and may reach its surfaces. The isolating regions form a rectangular or other shape cell on the first surface of the semiconductor layer, each cell encloses the anode/cathode region of a single photodiode of the array.

The isolation regions may be created by trenches or through vias, backfilled with standard filler. Alternatively, these isolation regions may be formed by the second doping regions, or a combination of trenches with the second doping regions. In the former case (doping regions only), the second doping regions may extend from the first surface of the semiconductor layer through the semiconductor thickness reaching the second surface of the semiconductor layer. In the latter case (combination of doping regions with trenches), the second doping regions may extend from the first surface of the semiconductor layer through the semiconductor bulk and stop inside the bulk of the semiconductor layer, not reaching its the second surface.

The isolation may be completed in this case by trenches extending from the second surface of the semiconductor layer inside its bulk. In some embodiments the trench may reach the second doping regions. The sidewalls of the trenches may be doped to comprise portions of the second doping regions. In all cases, the second doping regions concentration may not necessarily be uniform along the path connecting the surfaces of the two semiconductor layers. Moreover, they may have gaps along this path, with a very low second doping concentration. The third doping region is located proximate to the second surface of the semiconductor layer and forms a common cathode/anode of the array. The second surface of the semiconductor layer has a passivation layer. The first surface of the semiconductor layer is attached to the support substrate using one or more intermediate adhesion, etch-stopping, and/or isolation layers. The through vias are made in these support substrate and intermediate layers to open the first and second doping regions on the first surface of the semiconductor layer. There could be at least one through via per cell reaching the first doping region of each photodiode. There could be at least one through via per array reaching the second doping region. Inside openings, the regions of the semiconductor layer proximate to its first surface are covered or enriched with silicide or other known in the industry material to provide good Ohmic contact to the semiconductor areas. The vias are used to create conductive paths with metal or other highly conductive material from the surface of the support substrate to the first and second doping areas. The vias may be backfilled with oxide, polysilicon, or other standard filler and the contact pads may be deposited on the top completing the structure of the backlit photodiode array. Alternatively, the metal that contacts the semiconductor doping regions may be patterned to form the contact pads.

The sixth set of embodiments of the present invention comprises methods to manufacture the backlit photodiode array bonded to the support substrate in accord with this previous fifths set of embodiments.

The seventh set of embodiments of the present invention provides ultra thin front illuminated photosensitive device and array structures that may employ standard semiconductor processing equipment. The devices of these embodiments are one dimensional or two dimensional arrays of photodiodes, each having a single semiconductor layer and many structural features similar or identical to the fifth set of embodiments. However, the main feature of this set of embodiments that distinguishes it from the fifth set is that the anode/cathode is formed on the second (top) surface of a semiconductor layer, which results in the anode/cathode region formed proximate to the very top of the finished device structure. Accordingly, through vias may be required in the top semiconductor layer to contact these anode/cathode regions and to bring signals to the bottom of the structure. Also, no vias through the top semiconductor layer may be required to contact the isolation regions.

The eighth set of embodiments of the present invention comprises methods to manufacture the front-illuminated photodiode array bonded to the support substrate in accord with the seventh set of embodiments described in the above paragraphs.

Many of the embodiments that result from the inventive art herein result from growth of an epitaxial layer of silicon upon a surface of silicon that has already been processed to determine doped regions. Other embodiments result from performing these epitaxial growth steps in repetitive fashion. In these embodiments, a first layer that is present in a starting material may have regions across the surface that have different doping characteristics. In some of these embodiments, the first layer features may be used to define parts of the photodiode array that have been disclosed in some of the previously discussed embodiments. However, still other features in this layer may comprise parts of other electronic components. In a non limiting sense, examples could include defining parts of NPN or JFET transistors, parts of resistors, parts of varicaps and other such devices in this layer.

In combination with the embodiments that result from performing multiple passes of epitaxial deposition, it may be possible to create still further embodiments of the current invention by similarly defining doped regions for various devices other than the Photodiode array components. As in the prior discussions, embodiments may result from combining these types of embodiments with different techniques to bond substrates to the substrate being processed or to create vias through either the surface being built, or alternatively in through the bulk of the substrate upon which the layers are being built.

Thus the present invention relates to thin photodiode array structures and methods of manufacturing the same. The active portion of the devices may be created in a semiconductor layer of the first conductivity type. As an example, this semiconductor layer may be comprised of silicon. It may be obvious to one skilled in the arts that other embodiments may derive from the use of other semiconductor materials than silicon.

The semiconductor layer has first and second surfaces. As an example, silicon layer may be used. In some embodiments of this invention, the basic cell architecture of the photodiode includes regions of the second conductivity type created on the first surface of the semiconductor layer and separated by intrinsic regions from the regions of the first conductivity type on the second surface of the device thickness layer. A plurality of regions of the first conductivity type with concentration heavier than the background of the unprocessed semiconductor layer is made between the regions of the second conductivity type on the first surface of the semiconductor substrate. Additionally, a plurality of regions of the first conductivity type with concentration heavier than the background concentration is made on the second surface of the semiconductor layer and may be aligned with the plurality of regions of the first conductivity type on the first surface. The two aligned regions of the first conductivity type created on opposite surfaces of the semiconductor layer may be in contact, in some embodiments, through doped regions that pervade from both faces of the semiconductor layer used to define the active portion of the device.

As long as a sufficient portion of incident photons are absorbed in the body of the device, additional device thickness serves no purpose except for allowing a sufficient substrate thickness for the processing of the devices and their interconnections to outside contact points.

In some embodiments of this invention, thin processing of the active portion of the semiconductor device is accomplished by bonding of the semiconductor material onto another semiconductor substrate where some level of device processing has occurred. Still further embodiments may derive when non semiconductor material substrates are bonded to the active portion of the device.

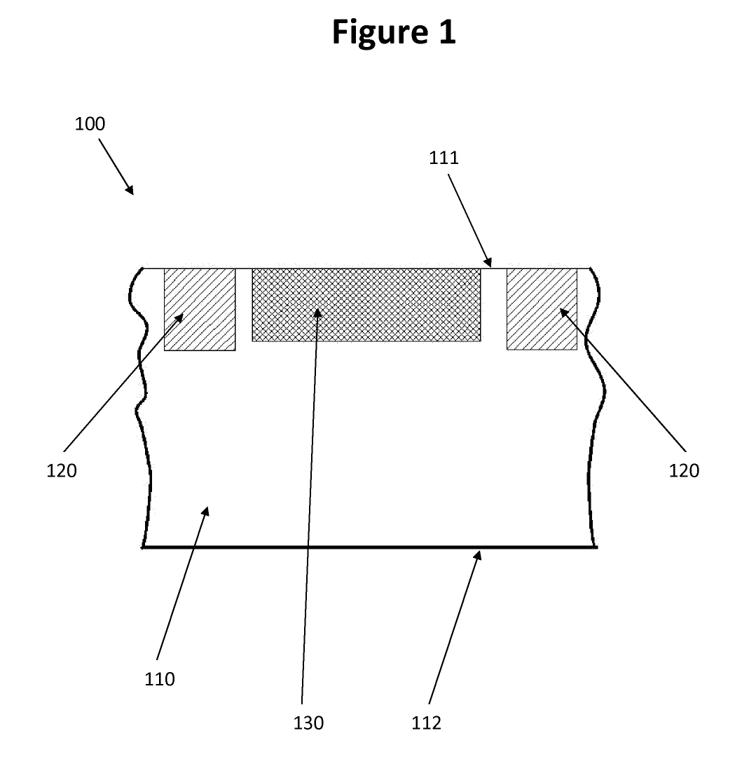

It may be possible to envision the steps of one embodiment by referring to FIG. 1, item 100. A layer of electronics grade semiconductor 110 of the first conductivity type may have a set of alignment marks written into it. The layer has a first surface 111 and a second surface 112. A lithography step may next be performed on the layer surface 111 to define features 120—the plurality of regions of the first conductivity type with concentration heavier than that of the background concentration of the semiconductor layer 110. These regions may form a rectangular lattice structure on the surface 111.

Into these regions a heavy level of doping may be exposed to the semiconductor layer. For example, n type doping may be implanted into the semiconductor exposed regions using an Ion Implantation process step. In most steps of doping of this invention it may be apparent to one skilled in the art that thermal diffusion processes or ion implantation may comprise acceptable means for locally doping a region.

After regions 120 are doped a diffusion step may occur to drive the dopant into the bulk. There may be numerous means to effect the diffusion of the dopants herein. For example, a thermal furnace may be operated at a high temperature, for example 1100 degrees centigrade.

A next lithography step may define the plurality of regions 130 of the second conductivity type on the semiconductor surface 111. It may be apparent that in defining these regions the lithography step may either just define imaged regions of photoresist that may block implantation in selected regions or alternatively, films upon the surface of the substrate may be selectively removed in the lithography defined regions therefore allowing diffusion processes to occur into the semiconductor. It may be apparent to one skilled in the arts that numerous means of defining the location of doped regions in these embodiments may comprise elements of the art herein.

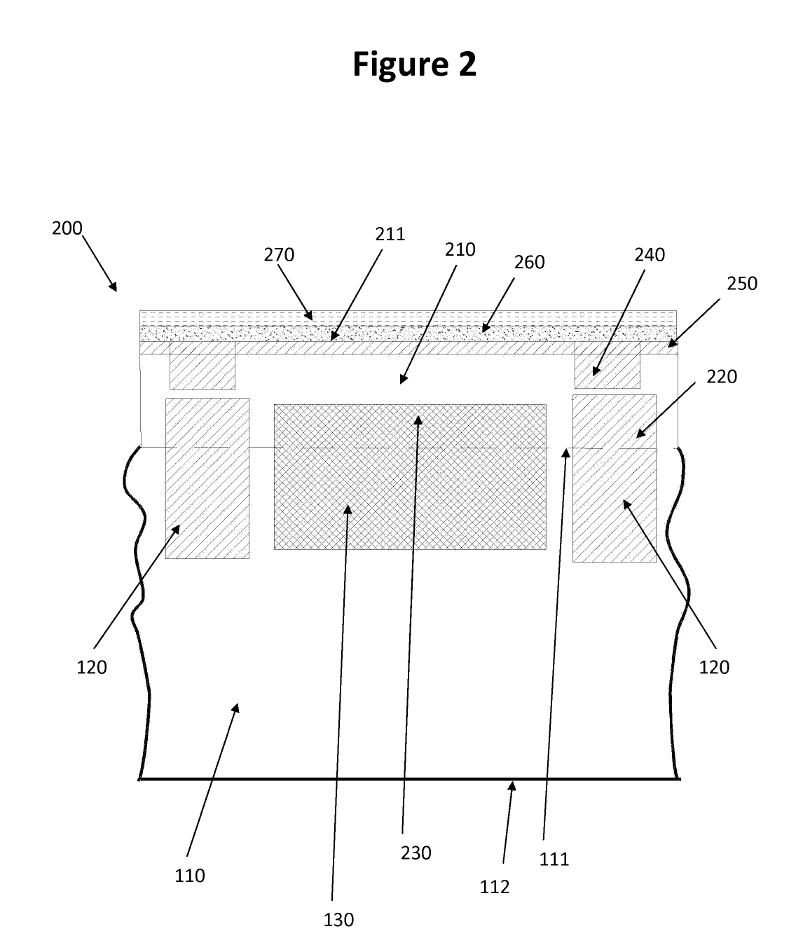

Item 130 may be defined with a P type dopant. Again in some embodiments a thermal diffusion process may drive the dopant into the bulk of layer 110. In some embodiments, after the definition of regions 120 and 130, an epitaxial growth step may occur. Such a step is shown in FIG. 2, item 200, and may define item 210 upon the surface of layer 110. In some embodiments, special processing focus may be performed to insure that the epitaxial layer is a very pure and high resistivity material for optical performance.

The resistivity of an epitaxial layer 210 may be either higher or lower when compared to that of the semiconductor layer 110. By way of non limiting example, the epitaxial layer may be grown with roughly 500 Ohm-cm resistivity and be roughly 30 microns thick. It may be apparent to one skilled in the art that numerous embodiments of different resistivity and epitaxial layer thickness may comprise consistent definitions of the epitaxial layer consistent with this art. And, further embodiments may come from a variation of certain layer characteristics including, for example the resistivity, while the layer is being grown. Still further embodiments may be derived from performing the epitaxial layer definition in numerous steps.

During the growth of layer 210, the doped regions of the layer 110, items 120 and 130 will diffuse into the epitaxial layer as items 220 and 230 respectively. Additional thermal processing may occur in some embodiments to more deeply diffuse these items into the grown epitaxial layer. Some embodiments may derive from the thermal processing of the semiconductor in the epitaxial deposition tool itself, or alternatively a separate thermal processing step may be performed in another thermal processing tool, like for example a furnace.

In further embodiments, the surface 211 of the epitaxial grown layer 210 will be processed with lithography steps to define regions 240. Into these regions in many embodiments with methods similar to those used to form regions 120, the first conductivity type dopant regions may be defined. Further thermal processing may be used to drive the regions 220 and 240 toward each other within the epitaxial grown layer 210.

In some embodiments, the dopant regions of 220 and 240 may touch or overlap. Other embodiments may include these layers being close to each other but not necessarily overlapping. It may be apparent to one skilled in the arts, that a significant diversity of processing embodiments may comprise results consistent with the formation of elements of a photo detector array.

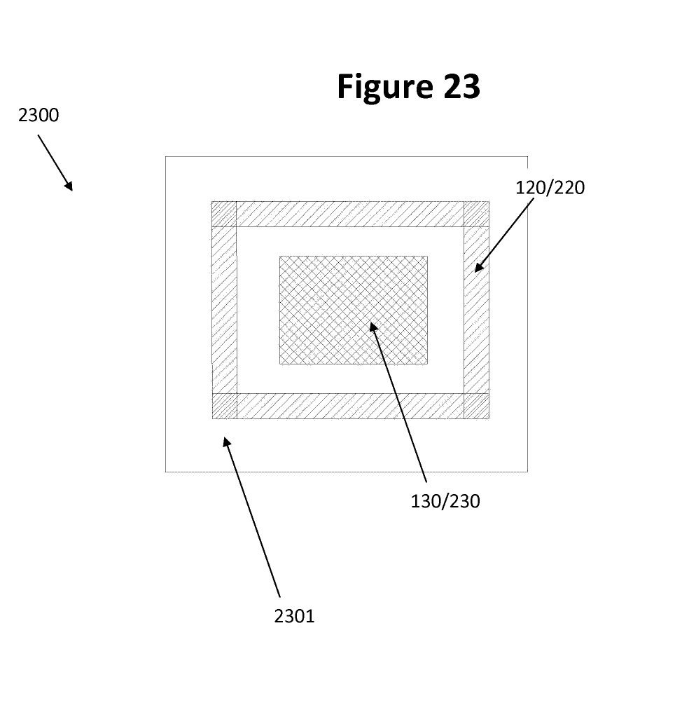

In some embodiments, the regions 120 and 220 may abut the regions 130/230 of the second conductivity type along the interface shown by the dashed line 111 in FIG. 2. In some embodiments, such abutting may provide a rectangular shaped structure shown in FIG. 23, item 2300 wherein a cross section of a single photodiode, item 2301, along the surface shown by the dashed line 111 is depicted.

In some embodiments additional processing may occur to define a layer 250 of the same conductivity type as regions 240 across the device surface. In some cases, this layer may be defined as a narrow feature at the very surface of the epitaxial layer. In these embodiments it may be preferential to limit thermal exposure of the device in subsequent steps so as not to significantly thermally diffuse the defined layer 250. Further embodiments may be defined by using a dopant species for layer 250 that while the same conductivity type as 240 may include a species that diffuses less rapidly for any thermal exposure that may be necessary for subsequent processing. It may be apparent to a skilled artisan that the numerous options for doping a semiconductor layer to form one type of doped region comprise consistent scope for embodiments in this art.

Some embodiments will further process the device by forming a film 260 of insulating material. As a non limiting example, the film 260 may include silicon dioxide that has been either thermally grown onto the surface 211 or deposited by various means onto that surface. In some embodiments, this film will comprise an optically relevant portion of the path photons may take in impinging the photodiodes of this invention. It may be important that the characteristics of this film therefore are tuned to optimize the photodiode sensitivity.

Additional embodiments may derive from the thickness aspect of the film 260 as formed. In some cases, a small thickness may provide advantages in the detection of photons impinging on the photodiode through layer 250.

In some embodiments, subsequent processing of the thin photodiode device may involve the bonding of a substrate onto the surface where insulator film 260 has been formed. As this substrate may later be removed, in some embodiments, it may be advantageous to define a protecting layer, shown in FIG. 2 as item 270. This layer may include, in a non limiting sense, a film of polysilicon. Polysilicon could be useful as it may be oxidized to form a bonding layer upon it. As well, many processes can differentially process oxide materials from polysilicon materials. In those cases, the polysilicon film can be effectively used as a stop layer, thus protecting the insulator film 260 from damage during removal of a bonded substrate.

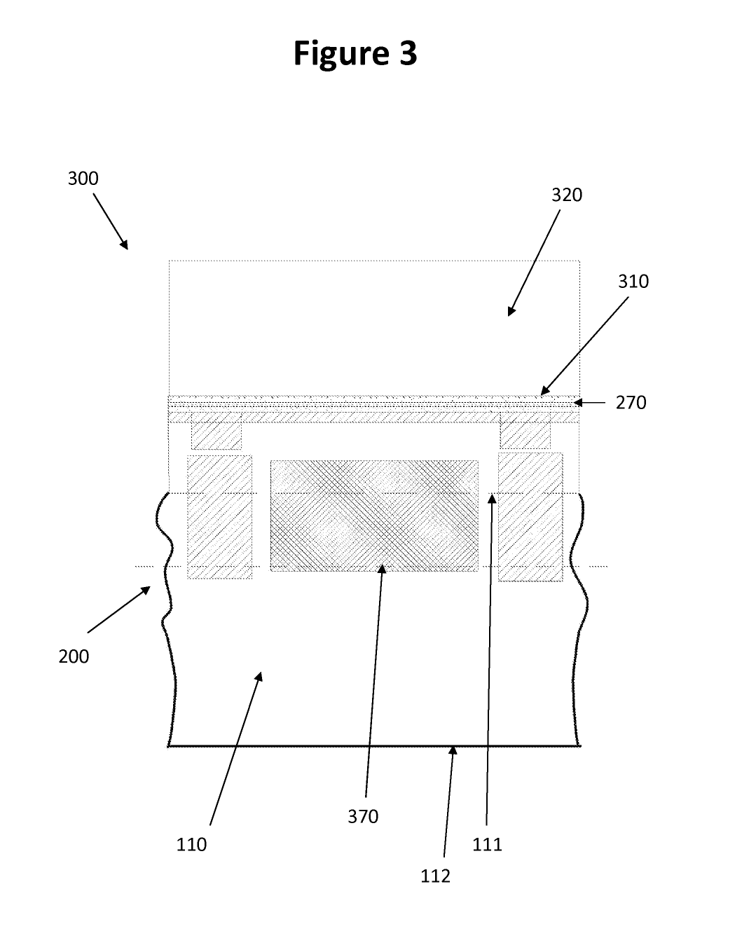

Proceeding to FIG. 3, item 300, in some embodiments a film of bondable oxide may be deposited or grown into a protective layer 270 as part of item 200. This bondable film may be seen as item 310. Using the various processes of substrate bonding a uniform bond film may be formed between a handling substrate, 320 and the oxide bonding film item 310. By way of non limiting example some embodiments may perform the bonding by pre-treating the surfaces to be bonded with a plasma treatment. With pressure applied between layers 320 and the underlying processed substrate 200 along with thermal processing will result in a permanent bond at the interface with film 310, when the surfaces are sufficiently planarized before the pressure treatment. In some embodiments, the resulting thickness of the two bonded wafers is large enough to allow a significant removal of the exposed surface 112 of the semiconductor layer 110. It may be obvious to one skilled in the art that the various types of materials that may be bound to the semiconductor layer 110/210 ranging from semiconductors to non semiconductor substrates are consistent with the invention herein described.

It may be noted that the dashed line 370 in FIG. 3 is shown for reference and indicates the depth of semiconductor removal by grinding, lapping, polishing, and/or other standard means from the exposure surface 112.

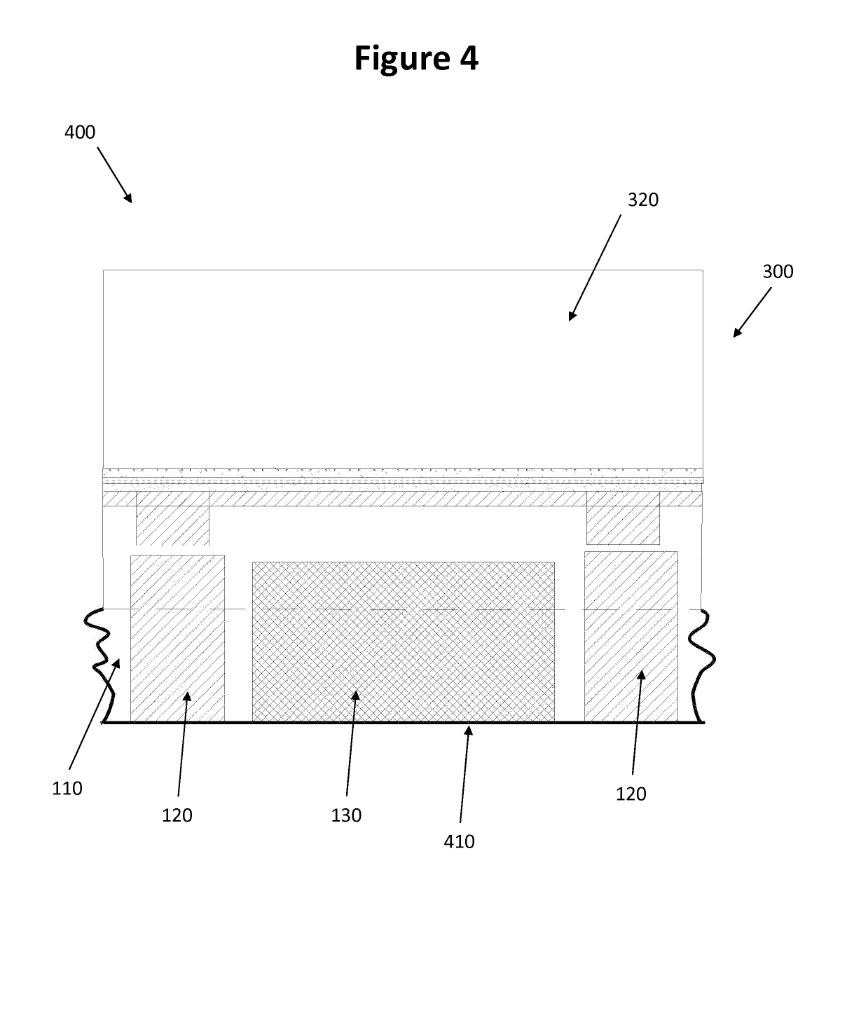

Referring now to FIG. 4, item 400 the bonded composite wafer item 300 is shown after the exposed surface 112 (FIG. 3) is processed. The composite wafer can be thinned by standard processing. In some embodiments this may include grinding the wafer to remove a gross amount of semiconductor layer from the 112 side. Next, in such embodiments, the surface could be processed with chemical mechanical polishing to provide a consistently smooth surface shown as item 410. In some embodiments enough material is removed to result in a bottom surface 410 that intercepts the diffused regions 120 and 130 of the initial wafer processing. It may be apparent to one skilled in the art that numerous methods of thinning, eroding or etching semiconductors may be consistent with the intents of the invention herein.

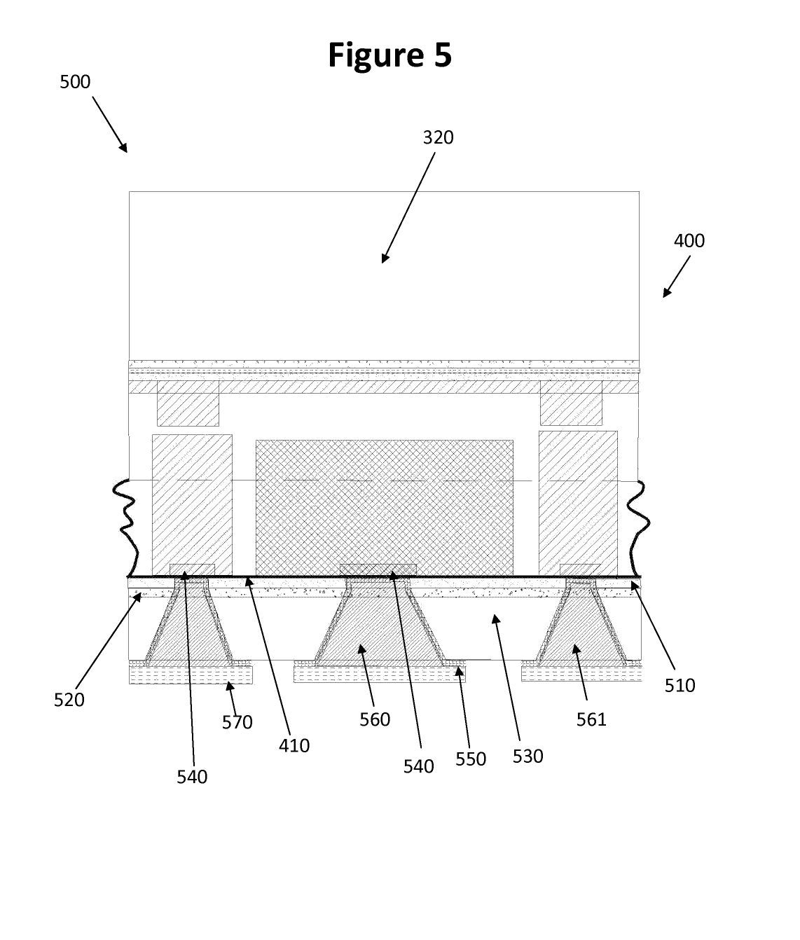

Next referring to FIG. 5, item 500 electrical connections may be made to the exposed diffusions regions on the newly processed surface 410. In some embodiments, the thickness of the device region defined after the grinding step referred to in the discussion of FIG. 4 may be thinner than an application need. In such cases the layer 530 may simply comprise a deposited layer, for example of an insulator or a semiconductor, through which vias may be made.

In the more general case, however, a layer with substantial thickness may be required. In some embodiments, a glass, quartz or other insulator substrate 530 of an appropriate thickness may be bonded onto the device substrate 400 at the interface surface formed by layers 510 and 520. As an example, the item 510 is a passivation layer and item 520 is a bond (adhesion) layer. Alternatively, a silicon substrate could be permanently bonded directly to the surface 410. By way of non limiting example, item 530 may include a Schott Glass (Mainz Germany) 0.1 mm thick glass substrate of material AF32. When bonded this exemplary material may withstand some thermal processing conditions.

Before layer 530 is defined or bonded, in some embodiments the dopant level of the exposed device contact regions may be insufficient to form a low resistance ohmic contact. A passivation layer 510 may be grown or deposited, in some embodiments, onto the contact side surface 410 of the formed substrate 400. Contact openings may be defined into this passivation layer 510 for the different diffusion regions. In some embodiments enhancement diffusions or implantations with dopants of the corresponding types may be made into the surface where contact will be made in either or both of the diffusion types as shown by item 540.

The implants may be subjected to an activation anneal, in some embodiments with rapid thermal annealing processing. In other embodiments, ohmic contact may be made by forming a silicide at the contact opening. For example, some embodiments may use a titanium deposition process. Thermal reaction of the titanium with exposed silicon, if the semiconductor is silicon, will form a good contact definition and in the insulator regions will not form a silicide. It may be clear to a skilled artisan that numerous materials may react with or interact with a doped semiconductor layer to form an acceptable layer of an appropriate contact resistance.

A wet chemical etch, standard in the industry, selective for titanium and titanium nitride versus titanium silicide may allow for electrical isolation of the contact regions.

In some embodiments, a layer 520 of insulating material, oxide or glass frit may be employed to affect the bonding of item 530 to the substrate 400. In some embodiments this layer 520 may be patterned to align with the desired contact regions 540. It may be apparent to one skilled in the art that numerous options and materials exist for the bonding of an insulating substrate to a silicon device substrate which may comprise aspects of the art disclosed herein.

Contact vias or openings may need to be formed in the layer 530. These openings, in some embodiments may be formed by lithographically defining openings in a resist layer and chemically etching out material to form the outlining regions of items 560 and 561. As a non-limiting example, each element of the array has at least one item 560. Also, only one or a few items 561 may be made across the whole array. In other embodiments a reactive ion etching process may be used to form the openings. Generally, any process known to those skilled in the art may be employed for the purpose of opening regions in layer 530 to allow electrical interconnections to be formed to the substrate 400.

In some embodiments, a layer 550 may be deposited into the formed vias. This layer may, by means of non limiting example, be a doped polysilicon film. The conformality of a CVD deposited film of this type may be desirable in some embodiments when item 530 is an insulator substrate. In other embodiments, the layer 550 may comprise an evaporated or sputtered metal film. Still other embodiments may be defined by combinations of a CVD layer and a metal layer. From a general perspective, it may be obvious that any means to form an electrical contact in a via formed in the substrate material may comprise art consistent with this invention. In the case when the substrate 530 was a semiconductor, the layer 550 deposited on the sidewalls of vias 560 and 561 may comprise the sandwich of the isolating and conductive films, wherein the isolating film was deposited first followed by deposition of the conductive film.

After these layers 550 are formed, in some embodiments, a lithographic process may be employed to regionally etch away materials between contact regions to define isolated contact regions. In some embodiments, the regional definition may be used to also define the contact pads for external connection. In many embodiments a voided region will exist in the contact opening region 560. In some embodiments, a filling layer may be introduced into the voids to planarize contact opening. Numerous materials may be employed for this purpose, for example, by way of a non limiting example a spin on glass material may be deposited, spun on to collect material into the open vias but limit the amount of material outside them. A subsequent etching step may uncover the contact regions. In some embodiments this next etching step may employ a lithography process to open only specific regions of the material used to fill in the vias and potentially passivate the metal contacts.

In alternative embodiments a second level of metal 570 may be added after the vias 560 are filled in and etched back to expose the regions 550. In a non limiting example an Aluminum layer could be deposited upon the contact layer 550 to define item 570. In some embodiments additional materials may be added to this feature to allow for appropriate layers to place solder bumps or other interconnection solutions.

In some embodiments, the structure of FIG. 5 may comprise a complete device structure. In this case, by means of non-limiting example, the handling substrate 320 may comprise a substrate, transparent to a certain wavelengths of optical radiation; In another case, the substrate 320 may contain a scintillator material and perhaps collimators. As an example, a fiber optic scintillator (FOS) plate may be used. In yet another embodiment, the scintillator material and collimators may be incorporated in a second optical substrate, bonded to the first substrate 320.

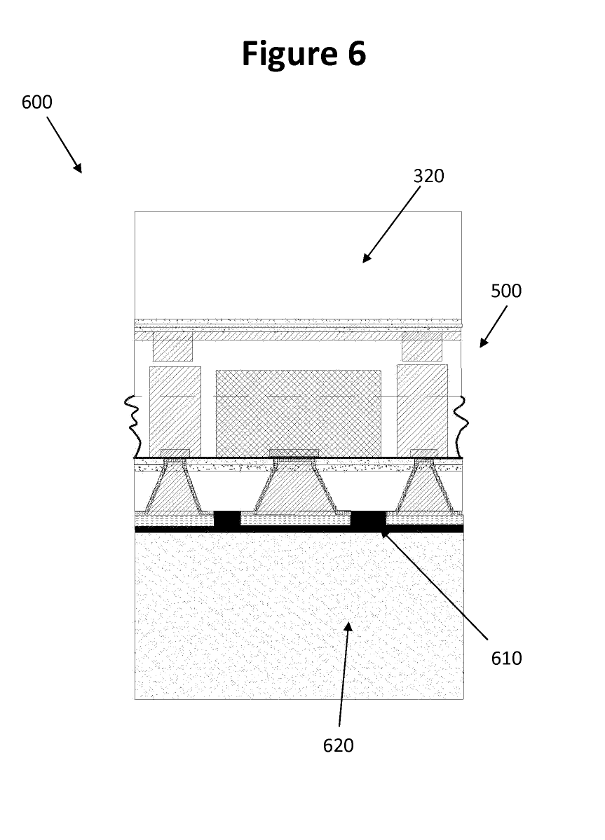

Proceeding to FIG. 6, item 600, the device in many ways may comprise a complete structure. However, a first handling substrate 320 is still present upon the backside of the photodiode device. Light may need to be able to enter from this side of the device, and in these embodiments the material of the handling layer may need to be removed. In some embodiments, it may be beneficial to temporarily bond a second handling substrate 620 upon the device 500. There may be numerous manners to temporarily bond two substrates known to one skilled in the art, and for example a UV sensitive adhesive may be used to define layer 610 that adheres the handling substrate 620 upon item 500. In these embodiments, after subsequent processing is complete the temporary handling substrate may be removed by exposure of the adhesive 610 to UV light through the substrate 620. In these embodiments therefore, it may be necessary to use a substrate 620 which is transparent to the UV wavelength used.

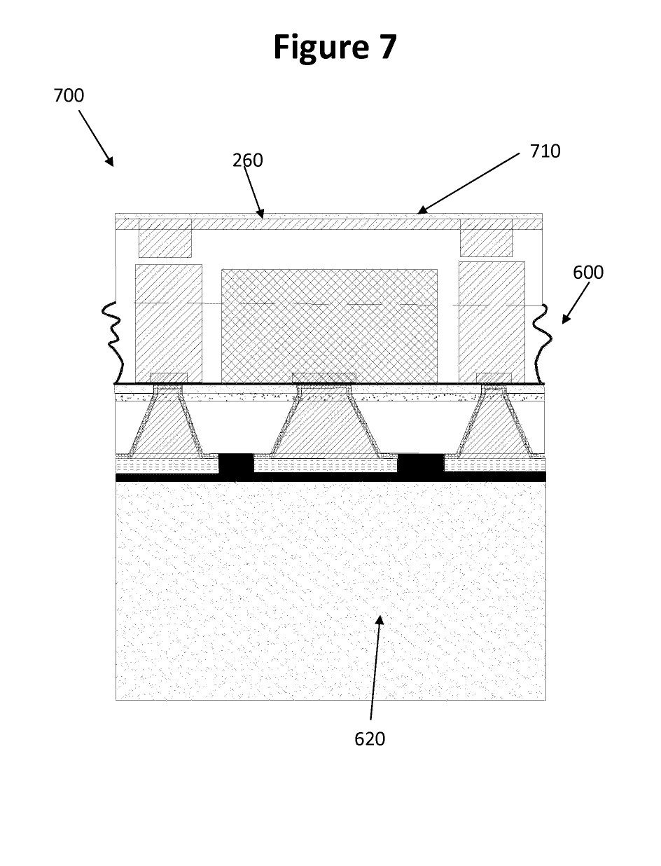

In some embodiments after a temporary substrate 620 is bonded the first handling substrate 320 may be removed. Referring to FIG. 7, item 700, it may now be seen that the composite device with temporary handling substrate 620 bonded—item 600 has now had the surface 710 on the backside of the photodiode ground down. In some embodiments after a gross grinding operation has occurred, the sample may be polished until the insulating film 260 is reached. In other embodiments, a reactive ion etching step may occur after grinding or after grinding and polishing. This chemistry may be chosen to be selective to the insulating film (for example, an oxide film) and it may therefore be possible to stop on the film. In other embodiments the insulating film 260 may be replaced after the handling substrate 320 has been removed.

In some embodiments where a temporary substrate, 620 has been used and removed it may be necessary to subject the otherwise finished device to cleansing steps of plasma treatment and/or chemical cleaning. After any such cleans are performed a functional thin back illuminated photodiode device may result.

It may be noted that other methods may be appropriate for thinning the first handling substrate item 320. There is grinding equipment that processes an interior region of the substrate. By way of non limiting example, equipment from Disco Inc, Tokyo Japan may be used to perform the so-called Taiko process. The lip around the edge of the substrate may be sufficiently robust to allow the processing steps described around item 600 in FIGS. 6 and 7 to be performed without the need of an additional temporary bonding substrate 620. In a more general sense, use of the Taiko or similar process for wafer grinding may allow for the fabrication of the thin back illuminated photodiode devices within this invention with or without the use of bonded handling substrates of the various types described.

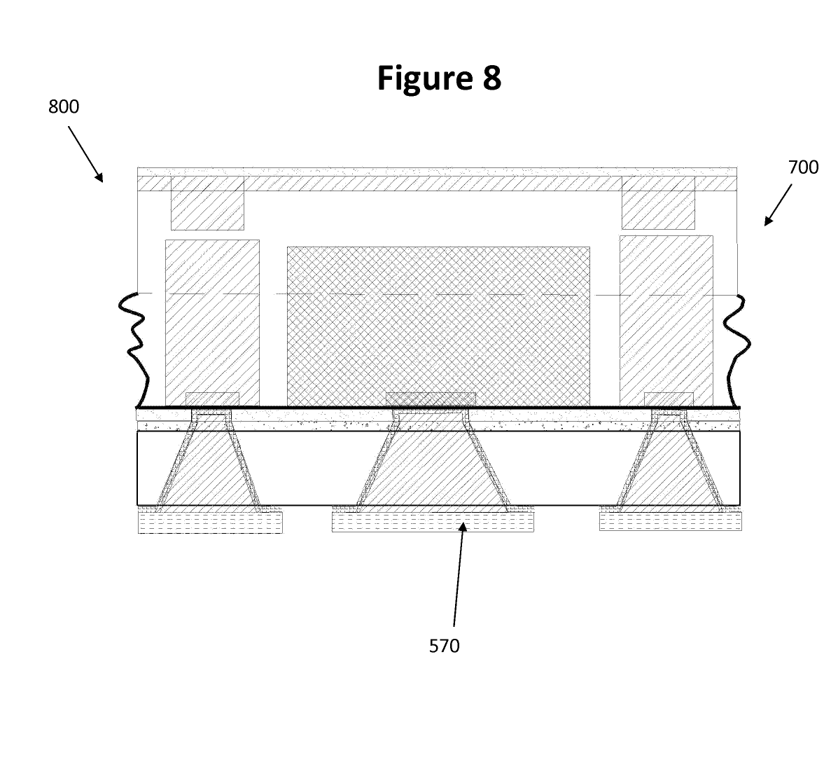

FIG. 8 is an example of the final structure 800. The metal pads 570 may require cleaning to support bumping. In some embodiments, a set of multiple isolation region combinations 120/220/240 may be formed between elements of the array. Yet another set of embodiments may provide isolation regions that enclose elements of the array completely. Alternatively, the isolation regions 120/220/240 may comprise partial enclosure of each element of the array.

Another set of embodiments may describe structures similar to those shown in FIG. 8 but comprising front-illuminated photodetector devices. As the main features of the embodiments describing such devices, the region of the second conductivity type with the dopant concentration heavier than the background concentration may be applied at the very end of the thermal processing flow to allow this region to remain shallow, in a close proximity to the surface 211 (top surface of the device structure) of FIG. 2. No blanket doping of the first conductivity type will be required on this surface. Instead, a heavily doped layer of the first conductivity type may be applied on the surface 410 of the first semiconductor layer of the structure. For those skilled in the art it may be obvious that to complete the front-illuminated structure of this type, one may provide a through via contacting the regions of the second conductivity type on the top surface of the device structure and bringing the signals to the bottom surface of the device structure. In some embodiments, the sidewalls of those vias may be coated with insulator (dielectric). In yet other embodiments, the conductive later may be aligned inside vias to connect features on the device surfaces.

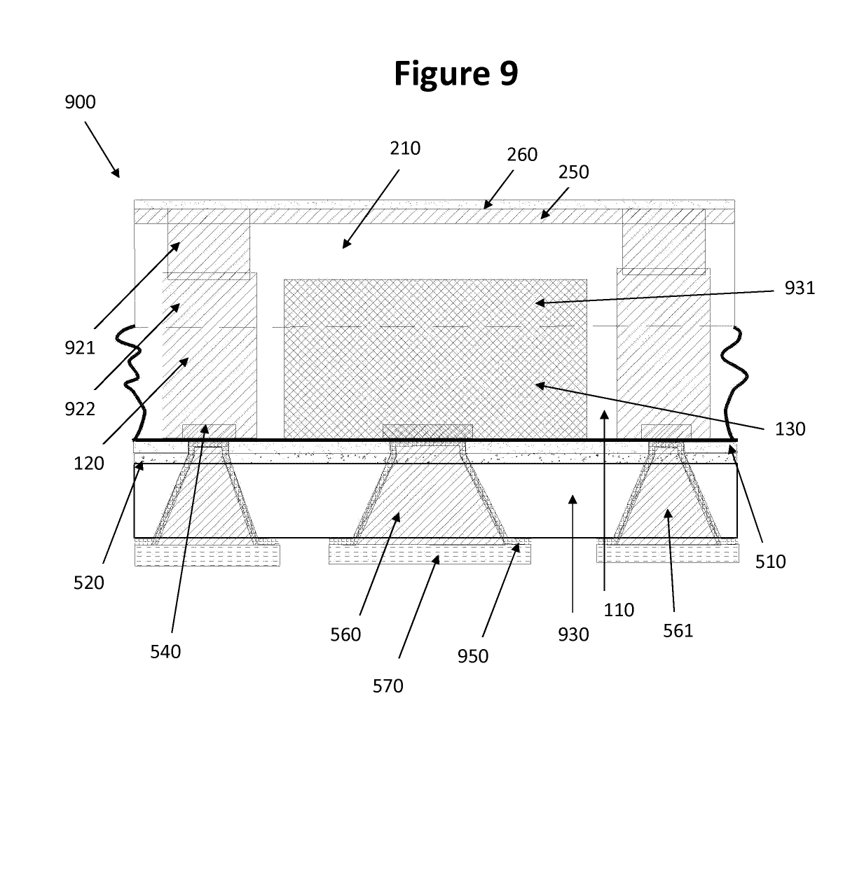

FIG. 9, item 900, is another example of the final structure, in which isolating regions of the first conductivity type 921 (an analogue of the region 240 in FIG. 2) and 922 (an analogue of the region 220 in FIG. 2) may touch or overlap. Since touching or overlapping regions 921 and 922 of the structure in FIG. 9 may require more extensive thermal budget or other process variations, the characteristics of the second conductivity type region shown as item 931 in FIG. 9 may also be different from those of item 230 in FIG. 2. As a non-limiting example, the film 950 deposited inside vias 560 and 561 may comprise a conductive layer (for example, a doped polysilicon layer, an evaporated or sputtered metal layer). The portions of the film 950 deposited on the sidewalls of the vias and the surface of the substrate may comprise a sandwich of the isolating and conductive layers. As a non-limiting example, each element of the array may have at least one item 560. Also, it may be possible that only one or a few items 561 may be located across the whole array. In some embodiments, the substrate 930 may be an isolating substrate. In other embodiments, this substrate 930 may be made of semiconductor material (for example, silicon). Similar to the case of FIG. 8, a set of multiple isolation region combinations 120/921/922 may be formed between elements of the array. Yet another set of embodiments may provide isolation regions that enclose elements of the array completely. Alternatively, the isolation regions 120/921/922 may comprise partial enclosure of each element of the array.

Yet another set of embodiments described by FIG. 9 may comprise isolation regions 120, 921, and 922 formed with the dopant of the second conductivity type, which is the opposite polarity to that of the substrate 110 and layer 210. The region 250 may also be of the second conductivity type. The regions 130 and 931 may be formed with the dopant of the first conductivity type having the concentration heavier than that of the substrate 110 and layer 210.

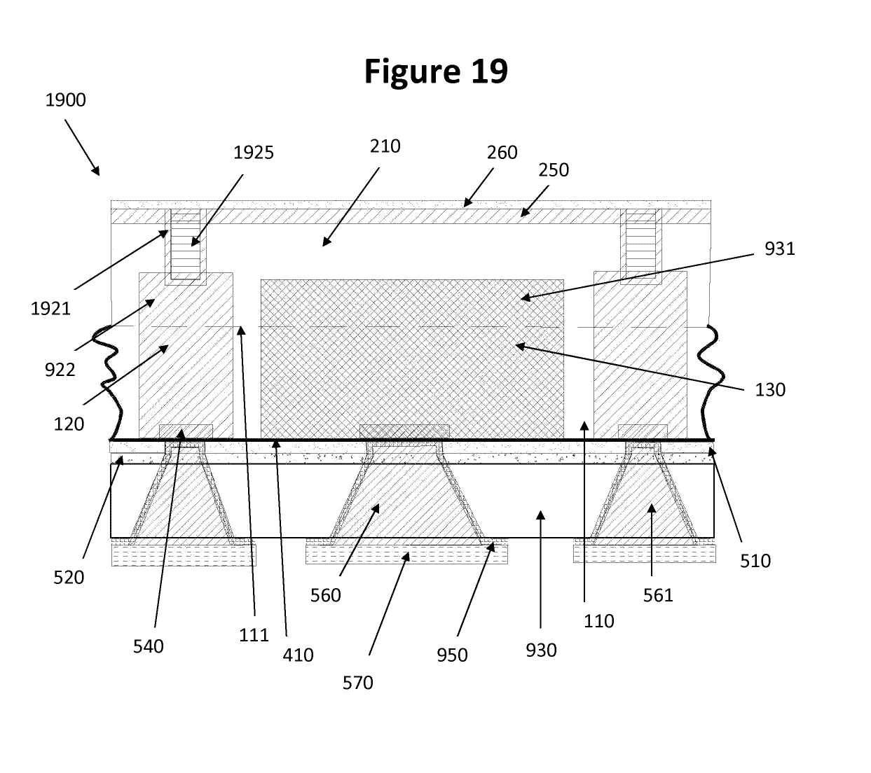

Yet another embodiment describing the final device structure is shown in FIG. 19, item 1900, in which the isolation regions may be made using a combination of the doping regions of the first conductivity type and trenches (these structures may be also referred to as vias). In one embodiment, the trenches outlined by the structures 1925 in FIG. 19, start on the surface of the semiconductor layer having the film 260 and penetrate inside the semiconductor bulk. In another embodiment, these trenches comprise a uniform grid on the surface of the array. In yet another embodiment, the sidewalls of trenches are doped with the regions 1921 of the first conductivity type with the concentration heavier than that of the background concentration of the semiconductor layer 210. As a non-limiting example, the trenches may be filled with a standard layers as described in other embodiments above. As another non-limiting example, the trenches 1925 may intercept the isolating regions 922. Alternatively, the structures 1925 and 1921 may penetrate through the surface item 111. Moreover, they may reach the surface 410 of the semiconductor layer 110. Similar to the case of FIG. 9, a set of multiple isolation region combinations 120/922/1925 may be formed between elements of the array. Some embodiments may provide more than one via 1925 between elements of the array. Yet another set of embodiments may provide isolation regions that enclose elements of the array completely. Alternatively, the isolation regions 120/921/922 may comprise partial enclosure of each element of the array.

Yet another set of embodiments described by FIG. 19 may comprise isolation regions 120, 922, and 1921 formed with the dopant of the second conductivity type, which is the opposite polarity to that of the substrate 110 and layer 210. The region 250 may also be of the second conductivity type. The regions 130 and 931 may be formed with the dopant of the first conductivity type having the concentration heavier than that of the substrate 110 and layer 210.

Another set of embodiments may describe structures similar to shown in FIGS. 9 and 19 but comprising front-illuminated photodetector devices. As the main features of the embodiments describing such devices, the region of the second conductivity type with the dopant concentration heavier than the background concentration may be applied at the very end of the thermal processing flow to allow this region to remain shallow, in a close proximity to the surface 260 (top surface of the device structure) of FIG. 2. No blanket doping of the first conductivity type will be required on this surface. Instead, a heavily doped layer of the first conductivity type may be applied on the surface 410 of the first semiconductor layer of the structure. For those skilled in the art it is obvious that to complete the front-illuminated structure of this type, one may provide a through via contacting the regions of the second conductivity type on the top surface of the device structure and bringing the signals to the bottom surface of the device structure. In some embodiments, the sidewalls of those vias may be coated with insulator (dielectric). In yet other embodiments, the conductive later may be aligned inside vias to connect features on the device surfaces.

An alternative set of embodiments of this invention derives from forming a photodetector array where the bonding process to a handling substrate occurs on the starting material before processing to determine elements of the photodetector array. Some examples of such a starting material may be a silicon on insulator (SOI) substrate. In some versions of this type of material a layer of silicon, which may be doped n type, p type or may be undoped is bonded onto a carrying (handling) substrate which has an oxide layer or buried oxide layer (BOX) on it. Underneath this oxide layer is a handling substrate which may be comprised of silicon, silicon oxide or quartz or a variety of other materials. In some embodiments, this type of bonded substrate may be formed by a Smart Cut implantation process, for example from SOITEC Inc, France; that results in thin silicon or other material layers that are bonded on an oxide covered handling substrate. Alternative, bonded and ground or polished silicon, or other material, on insulator substrates may also comprise an acceptable starting material. As well there are processes where the buried oxide layer is formed by the implantation of oxygen atoms to form an insulator layer after thermal processing. It may be apparent to one skilled in the art that any of these starting material embodiments may comprise an acceptable starting material for the embodiments which follow and therefore add to the diversity of embodiments that may be anticipated within the scope of this invention.

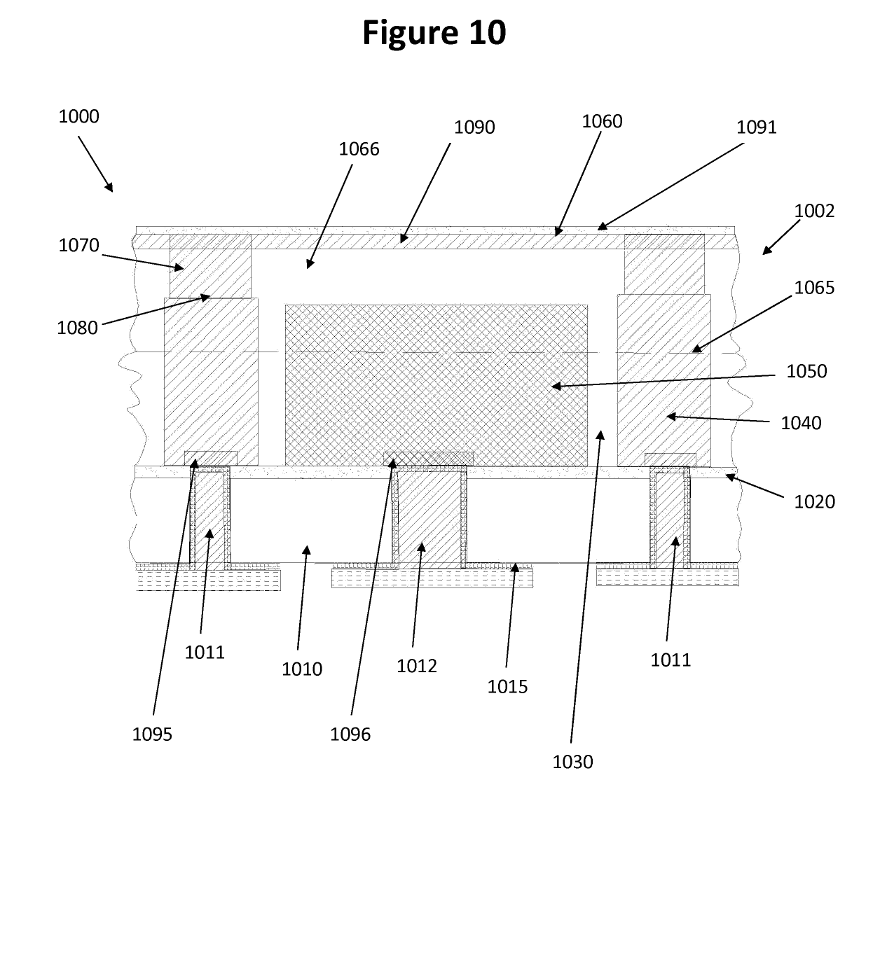

Proceeding to FIG. 10, item 1000, an example representing one embodiment type from this type of device is shown. To obtain a device of this type, a starting material of the types mentioned may be used. This material, item 1002, may have a handling substrate 1010 and an insulator layer 1020 that separates but supports the top most layer 1030. It should be noted that the relative dimensions in this figure and others with this type of starting material are not meant to reflect likely dimensions. In many cases substrate component 1010 may actually be many times thicker than the other components. For ease of demonstration it is shown in the relative size of item 1010 for example. In some embodiments this top most layer may comprise silicon. However, it may be apparent that many different materials may comprise layer 1030, with some examples being III/V and II/VI semiconductor layers, graphene layers or other materials from which photodetector arrays or more generally detectors of electromagnetic radiation may be manufactured from.

The component 1030, for example, may have a silicon top material layer where that layer has been doped with the dopant of the first conductivity type and comprises a thickness of approximately 1 micron. In a manner that is similar to the processing shown in FIG. 2, regions of the top silicon material layer 1030 may have regions that are masked off by photo lithography steps and then doped with the first conductivity type regions 1040 and the second conductivity type regions 1050 (both in the concentration heavier than the background concentration of the layer 1030). It may be apparent to a skilled artisan that the actual nature of these regions may have broad diversity including for example being formed as the opposite type as just described for example.

This composite substrate 1010/1030 may then be processed with epitaxial processing steps as discussed to obtain a new bulk, item 1066, with a new top surface shown as item 1060. The original surface of the top layer before the epitaxial growth occurred is represented in the FIG. 10 by the dashed line, item 1065. As previously discussed, during the processing of the epitaxial layer, which may occur at temperatures of 1000 degrees centigrade or more, the dopant regions that were formed into the starting layer 1030 will diffuse over the processing time. It may be apparent to one skilled in the arts that there may be numerous manners in which the epitaxial process may be performed. The process temperature, process reactants, dopant levels in the gas phase and numerous other process operational options all define a scope consistent with the inventive art herein.

In some embodiments, to continue with the processing, the new top surface 1060 of the device layer may now be subjected to lithography processes to further define regions of the isolation. For example, the first conductivity type regions of dopant 1070 with the concentration heavier that the background concentration of the layer 1066 may be formed to align with the regions item 1040 by lithographic processing. With further processing, in some embodiments, the various dopant regions may be diffused under thermal processing to diffuse into neighboring regions of the device layer 1030. In some embodiments, the diffusion may proceed to cause the top and bottom features to overlap each other as shown in FIG. 10 by the arrow at item 1080.

In some embodiments, a set of multiple isolation region combinations 1040/1070/1080 may be formed between elements of the array. Yet another set of embodiments may provide isolation regions that enclose elements of the array completely. Alternatively, the isolation regions 1040/1070/1080 may comprise partial enclosure of each element of the array.

In an example embodiment, the substrate may then be subjected to a blanket implant step to form a doping region 1090. Thermal processing may then be used to activate the dopants that have been formed in this layer. In some embodiments, a thin oxide film item 1091 may be formed during this activation processing. Alternatively, a thin oxide film may be formed in a subsequent growth or deposition step to form such a film. It may be obvious to one skilled in the arts that there could be numerous acceptable layers consistent with the optical needs of the device that could be formed here and that the material, thickness and other aspects of the film may be varied in a manner that is consistent with the inventive art herein.

In some embodiments, the resulting surface could be bonded to a new substrate and processed in a manner described in the initial embodiment discussion starting with the discussion of FIG. 5. However, the processing on the SOI substrate allows for a further set of embodiment options. In some embodiments, the resulting substrate comprised of a handling part 1010, an insulator layer 1020 and a formed device later of some embodiment thereon, may be thinned to a particular overall device thickness as required for particular applications.

After thinning, the back layer of the substrate that remains may be processed by a technique to create vias, 1011 and 1012, which penetrate the handling substrate 1010 and the insulator layer 1020. As a non-limiting example, there may be at least one via 1012 per element of the array and at least one via 1011 per whole array. The via may then allow electrical connection to the various doped regions of the initially formed layer, for example items 1040 and 1050 through the ending features 1095 and 1096. Any of the standard methods of forming a thru substrate contact via would define embodiments consistent with the inventive art herein. As well, as an example, the processing of thru vias was described to occur after the handling region of the substrate 1010 was thinned. Other embodiments may occur with processing of the vias occurring before the substrate is subjected to thinning steps. Still further embodiments may be possible where the via hole is processed before thinning but not filled until after the substrate has been thinned by one of various means. It may be apparent to one skilled in the arts that any method of defining a contact through a substrate to an active layer defines embodiments consistent with the art herein. The conductive layer 1015 is deposited inside vias 1011 and 1012 to provide electrical connections to the semiconductor regions 1095 and 1096. In the case where the substrate 1010 was a semiconductor, the portions of the layer 1015 deposited on the sidewalls of the vias may comprise a sandwich of an isolating and conductive film.

In some embodiments, enhancement diffusions or implantations with dopants of the corresponding types may be made into the semiconductor regions 1095 and 1096, where contact will be made. In other embodiments, ohmic contact may be made by forming a silicide at the contact openings. For example, some embodiments may use a titanium deposition process.

Yet another set of embodiments described by FIG. 10 may comprise isolation regions 1040 and 1070 formed with the dopant of the second conductivity type, which is the opposite polarity to that of the substrate 1030 and layer 1066. The region 1090 may also be of the second conductivity type. The regions 1050 may be formed with the dopant of the first conductivity type having the concentration heavier than that of the substrate 1030 and layer 1066.

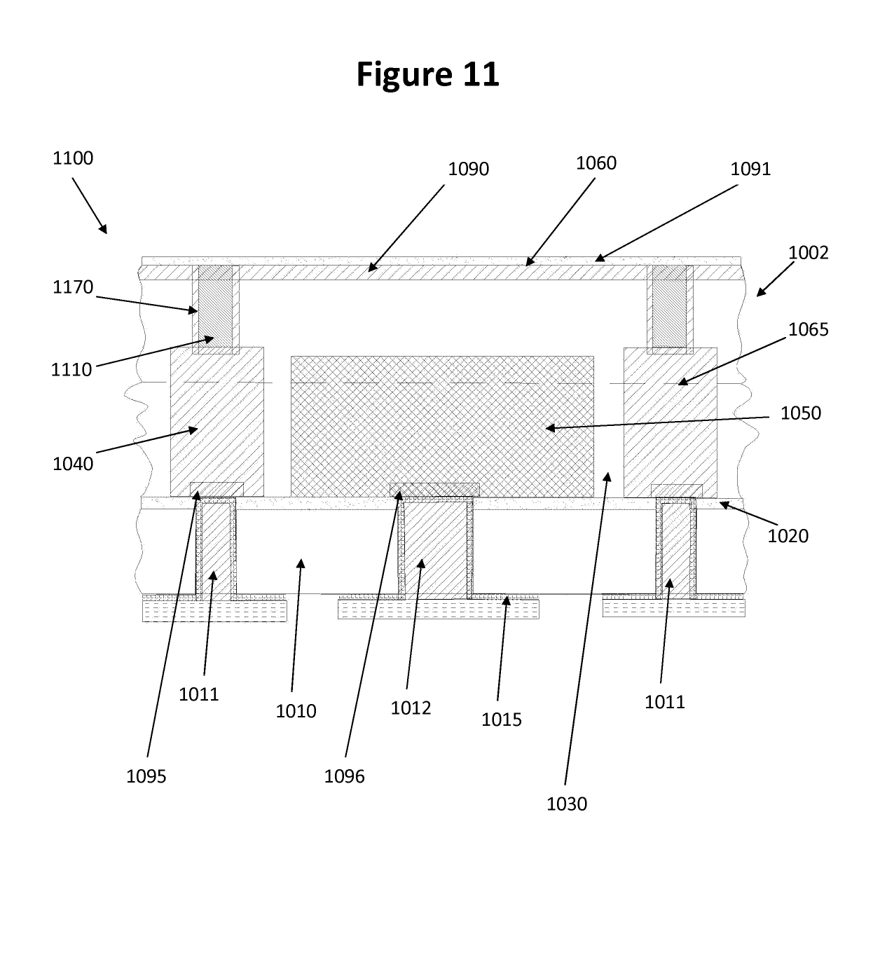

Other embodiments of the art herein are demonstrated in FIG. 11, item 1100. In FIG. 11, a starting substrate of the material on insulator type discussed in the embodiments related to FIG. 10 is again used and processed with epitaxial processing. Alternatively however, the thermal processing on such a substrate after defining various doped regions may be altered to be significantly shorter in duration. In some of these embodiments, the connection of the top surface region 1090 may be formed by the creation of a top surface via (which may be also referred to as trenches), depicted as item 1110 in FIG. 11. In some embodiments, as shown in FIG. 11, this via does not penetrate the entire device processing layer 1030 but rather is formed to a depth that terminates in a region of the semiconductor bulk where the doped feature 1040 has diffused into. As a non-limiting example, the sidewalls of the vias 1110 may be either doped with the first conductivity type dopant or covered with any other conductive material as shown as item 1170 in FIG. 11. It may be obvious that the various industry standard manners to form a via in a semiconductor layer and then have that via filled in such a manner to create electrical connection is within the scope of this art. Alternatively, the feature 1170 on the sidewalls of vias may be an isolating material. Moreover, the vias 1110 may be filled with either conductive material (for example, doped polysilicon) or isolating material (for example, glass or any other isolator or dielectric) As shown in FIG. 11 for reference, the embodiments for connecting through the substrate to the doped or undoped regions of the bottom of the semiconductor layer 1030 are consistent with this embodiment as are the variations possible as discussed in the section describing FIG. 10.

As may be obvious for a skilled artisan, a set of multiple isolation region combinations 1040/1110 may be formed between elements of the array. Yet another set of embodiments may provide isolation regions that enclose elements of the array completely. Alternatively, the isolation regions 1040/1110 may comprise partial enclosure of each element of the array.

Yet another set of embodiments described by FIG. 11 may comprise isolation regions 1040 and 1170 formed with the dopant of the second conductivity type, which is the opposite polarity to that of the substrate 1010 and layer 1066. The region 1090 may also be of the second conductivity type. The regions 1050 may be formed with the dopant of the first conductivity type having the concentration heavier than that of the substrate 1030 and layer 1066.

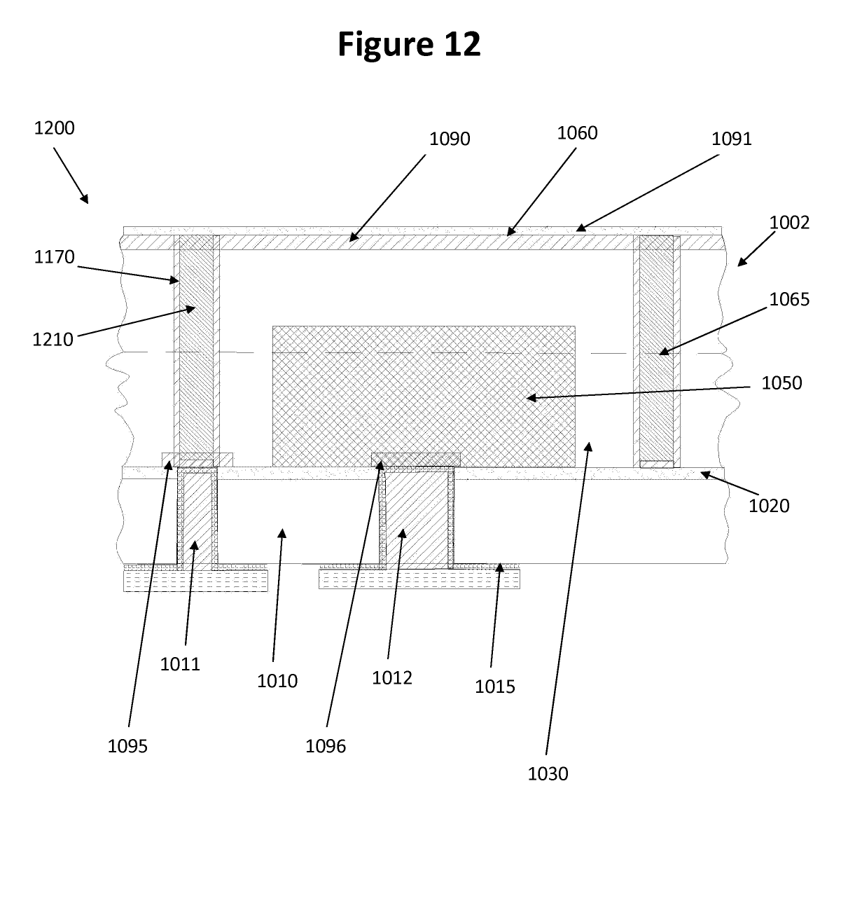

An alternative embodiment, sharing much similarity to the embodiment demonstrated in FIG. 11 is depicted in FIG. 12 as item 1200. The processing of this embodiment may have similar options as described in FIG. 11; however, in this case the via 1210 in the top surface 1060 of the device layer 1030 now penetrates fully through the top layer ending at the bottom of a doped feature 1095 for example. As a non-limiting example, there may be at least one via 1012 per element of the array and at least one via 1011 per whole array.

Similarly to the disclosure of FIG. 11, the isolation between elements of the array shown in FIG. 12, item 1200 may comprise multiple trenches 1210. Yet another set of embodiments may provide isolation regions that enclose elements of the array completely. Alternatively, the isolation regions 1210 may comprise partial enclosure of each element of the array.

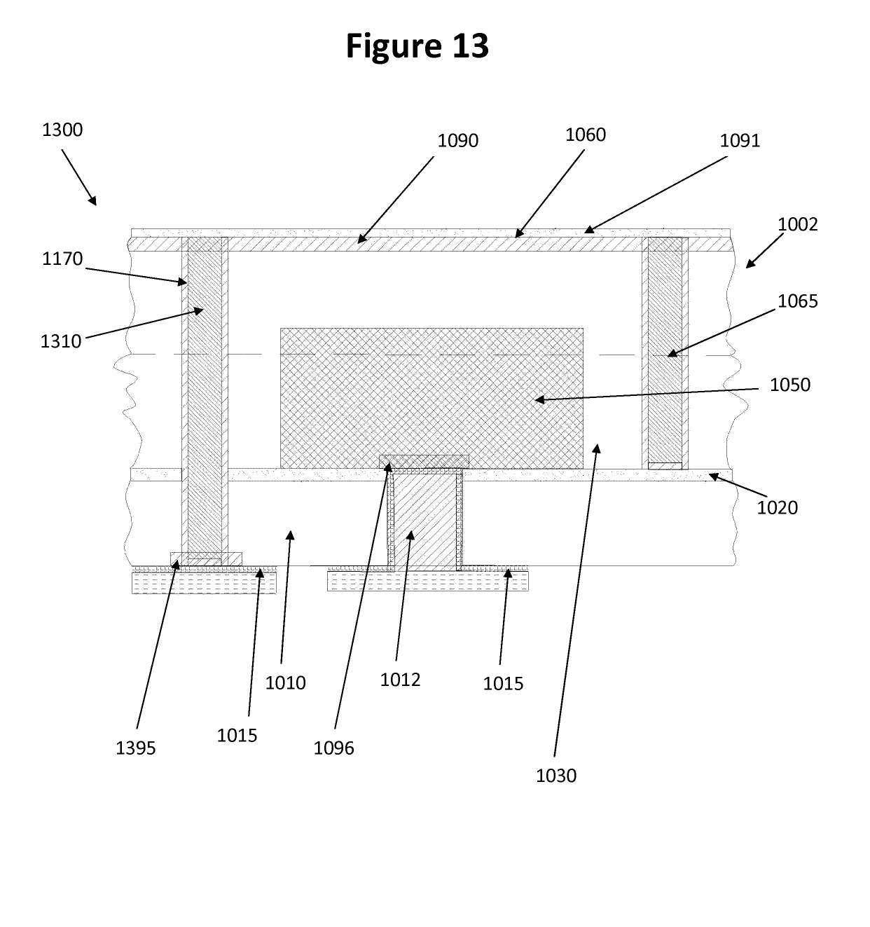

Still further embodiments may be derived from such similar processing as described for the embodiment descriptions related to FIGS. 11 and 12. In FIG. 13, item 1300, such an alternative embodiment may be seen in that the via 1310 shown in the figure now penetrates the entire semiconductor layer 1030, penetrates through the insulator layer 1020 and then through the handling substrate 1010 creating a singular feature that may be connected for device applications with the feature 1395 in a manner similar to that for features 1095 and 1096. As a non-limiting example, at least one features combination 1310/1395 may be provided per array.

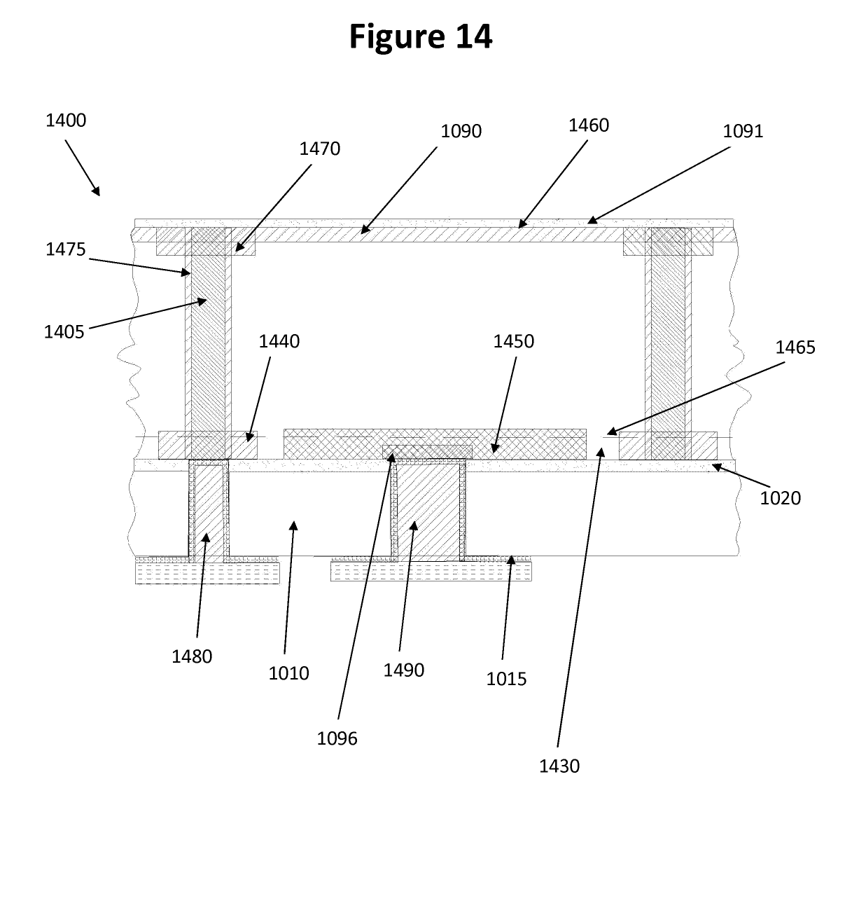

Proceeding to FIG. 14, item 1400, an example representing an alternative embodiment type using an SOI substrate as a starting material is shown. Embracing all the diversity in embodiments that resulted from discussing FIG. 10, in this figure many features are formed in similar manners to that of FIG. 10, and are numbered similarly in this figure. However, in the embodiment type represented in FIG. 14 the thermal processing is depicted as occurring with a minimal level of high temperature processing. The thickness of the semiconductor layer 1430 in the starting material may be very low. As a non limiting example, this thickness may be less than 1 micron. Regions on the top surface 1465 of the silicon layer 1430 may have regions that are masked off by photo lithography steps and then doped with the first conductivity type regions 1440 and the second conductivity type regions 1450. Again, it may be apparent to a skilled artisan that the actual nature of these layers may have broad diversity including for example being formed as the opposite dopant type as just described.

This substrate may then be processed with epitaxial processing steps as discussed to obtain a new top surface shown as item 1460. The original surface of the top layer before the epitaxial growth occurred is represented in the figure by the dashed line, item 1465. As previously discussed, during the processing of the epitaxial layer, which may occur at temperatures of 1000 degrees centigrade or more, the dopant layers that were formed into the starting layer 1430 will diffuse over the processing time. It may be apparent to one skilled in the arts that there may be numerous manners in which the epitaxial process may be performed. The process temperature, process reactants, dopant levels in the gas phase and numerous other process operational options all define a scope consistent with the inventive art herein.

In some embodiments, to continue with the processing, the new top surface of the device layer may now be subjected to lithography processes to further define doped regions. For example, the first conductivity type regions of dopant 1470 may be formed to align with the item 1440 by lithographic processing. Now however, no further significant diffusion is performed at this point. In some embodiments, a top surface contact or isolating via (which may be also referred to as trenches), item 1405 may be formed within the semiconductor layer. In some embodiments this via, when unfilled may be subjected to a doping diffusion process to create doped regions 1475 along the sidewalls and down the length of the via. Next the via 1405 may be refilled, and material used to fill the via removed from the top surface of the device. As a non-limiting example, the filling material may be conductive filler. Otherwise the filler may be an isolating material. Instead of having a significant thermal budget to process these layers, the via may create regions with both the contact and isolation properties. The options to define additional embodiments within this type of top via contact are intended to embrace all the previously mentioned options for further processing of such a device including using various types of vias to provide electrical contacts to semiconductor regions 1450 and 1440, as shown with features 1490 and 1480 or alternatively additional bonding processing as discussed in FIGS. 5 through 8 for example.

In some embodiments, the isolation between elements of the array item 1400 may comprise multiple vias (trenches) 1405. Yet another set of embodiments may provide isolation regions that enclose elements of the array completely. Alternatively, the isolation regions 1405 may comprise partial enclosure of each element of the array.

In other embodiments related to FIG. 14, no top surface contact or isolating via may be provided, which may result in the structure with an increased crosstalk but still useful for certain applications.

Yet another set of embodiments described by FIG. 14 may comprise regions 1440, 1470, 1475 and 1090 formed with the dopant of the second conductivity type, which is the opposite polarity to that of the substrate 1430. The regions 1450 may be formed with the dopant of the first conductivity type having the concentration heavier than that of the substrate 1430.

In the preponderance of these material on isolation type of embodiments, the examples derived from a discussion of a starting material where the starting material had a top semiconductor layer thickness, shown for reference in the roughly one micron type of thickness. As previously discussed, there may be numerous embodiments that are apparent to one skilled in the arts relating to characteristics of the starting SOI material.

In a specific reference, to provide additional description of the embodiments resulting from the inventive art herein, additional embodiments may derive when the semiconductor layer is significantly thinner than approximately 1 micron. In some embodiments, it may be roughly 200 angstroms thick. The resulting devices that may derive from this starting material may share significant structural similarity to those already described; however, by starting with a thinner substrate it may be apparent that the initial regions of dopant implanted into the top layer before epitaxial deposition may be initially localized much closer to the isolation (BOX) layer 1020 of the substrate. The nature of the thermal diffusion processes discussed herein may in some embodiments have a benefit under such localization. Furthermore, depending on the number of different doped regions in this initial semiconductor layer different embodiments may derive where localized dopant features are possible through the use of slower diffusing dopant species and lowered thermal processing times.

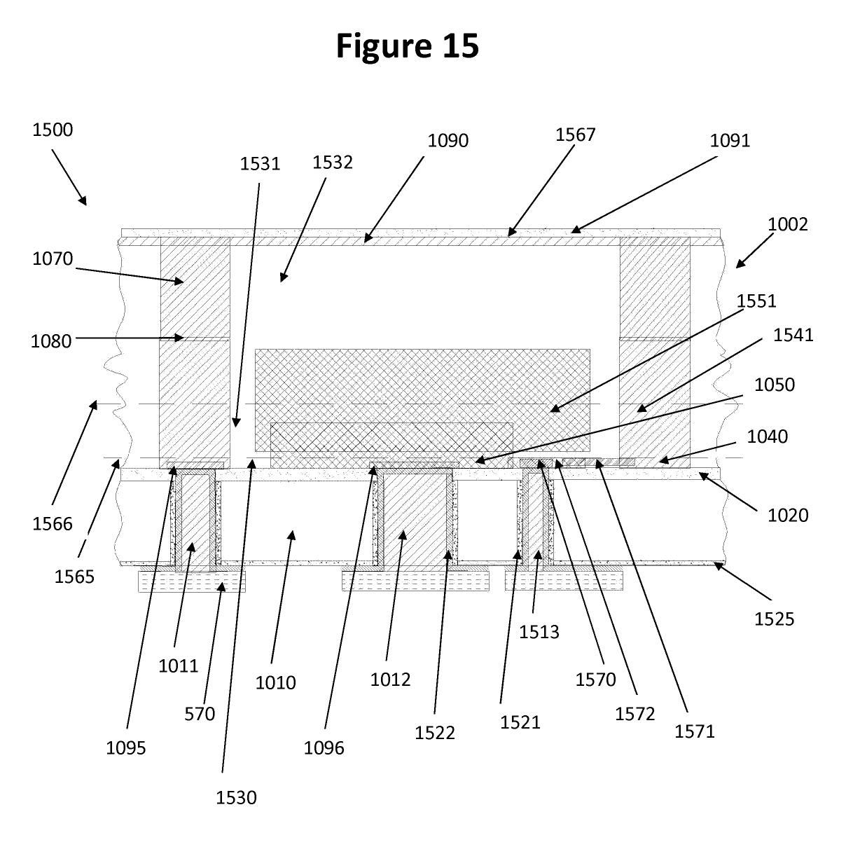

In an example of the type of embodiment that may derive from this processing, FIG. 15, item 1500, shows an exemplary depiction of a composite photodiode array device. In this composite device, both a photodiode and other active and passive devices may share the same silicon device layer. In, FIG. 15, an example where a starting silicon on insulator wafer with a thin top silicon layer 1530 having dopant of the first conductivity type and a top surface 1565. In the initial photolithography steps the standard photodiode region 1050 and isolation features—region 1040 may be defined. By means of example, the dopant of region 1040 may be of the first conductivity type and may include Phosphorous for example. Furthermore, the dopant species of item 1050 may be of the second conductivity type and may include Boron for example. Both of these features will diffuse relatively quickly during thermal processing. Items 1570, 1571 and 1572 however, show portions of an example of a composite device of the type mentioned herein. Items 1570 and 1571 may comprise the regions of the first conductivity type whereas item 1572 may comprise the region of the second conductivity type. As a non-limiting example, these features may comprise a type of lateral NPN device and may be arranged in the same silicon layer 1530. For reference, the species used to form this device may include Arsenic for features 1570 and 1571 and Antimony for example for feature 1572. These features may be expected to diffuse less under subsequent thermal processing. The inventive art contained in this feature embraces using these processing embodiments to allow for numerous device types to be defined into the initial layer. By way of non limiting examples, the type of devices that may be found in these layers may include transistors of various types (Bipolar, JFET, MOSFET, etc.), varicaps, resistors and the diversity of devices that may be formed from doped regions in a semiconductor layer.

In yet another embodiment different epi layers may be used to create different parts of the same structure; for example, the devices with internal amplification may be created by placing functionally different regions with opposite or the same polarity dopants into different epi layers. In such a way, for example, the photodetector array comprising avalanche photodiodes or the so-called silicon photomultipliers as elements of the array, may be created. One possible structure with an avalanche photodiode as the photosensitive element of the array will be discussed below.

Another set of embodiments may derive from the fact that the epitaxial growth process may be repeated. In the example of FIG. 15, it may be seen that two epi steps are depicted by the semiconductor layers 1531 and 1532. The intermediate layer 1531 may have the interim top surface shown with the dashed line 1566. The final top semiconductor layer 1532 has the top surface 1567. In a more general sense, it may be apparent that numerous process steps can be repeated between the processing of the epi growth steps. In this way a three dimensional processing of a device layer may be performed.

As an example, in FIG. 15, the first conductivity type region 1541 and the second conductivity type region 1551 may be formed on the interim surface 1566 of the intermediate semiconductor layer 1531. These regions may improve noise characteristics of the back-illuminated photodiode as well as collection of non-equilibrium carriers created through absorption of light. The regions 1070 of the first conductivity type may perform the same conduction and isolation functions as described previously in FIG. 10. In some embodiments, these regions may overlap with up-diffused regions 1541 as shown with the feature 1080. In other embodiments, the isolation structures may be created by vias (trenches) or their combination with diffusion regions similarly as shown in the features 1110 and 1210 in FIGS. 11 and 12, respectively. In another set of embodiments, the isolation regions between elements of the array may comprise sets of multiple combinations like 1040/1541/1070/1080 or multiple isolation trenches. Yet another set of embodiments may provide isolation regions that enclose elements of the array completely. Alternatively, the isolation regions may comprise partial enclosure of each element of the array.

In some embodiments, this multiple epi processing could be used to lower the total thermal processing required to cause the isolation regions 1040 and 1070 to join up with each other. In other embodiments, the isolation structures like vias 1110 or 1210 may be used in lieu of regions 1070. In still further embodiments the multiple epi processing may allow different features to be placed at different locations in the vertical structures. In a non limiting example, the very bottom semiconductor layer could be reserved for various active and passive devices like transistors and resistors. Further processing with multiple epi processing could then allow formation of the photodetector elements to occur on top of this device layer. The active device features could line up with the photodetector elements and then electrically act upon the signal that may be received in the photodetector element.

The structure in FIG. 15 may be completed by making vias shown with items 1011, 1012 and 1513. While the first two vias (1011 and 1012) serve the purpose of contacting the regions of the photodiode, the via 1513 was design to contact the region 1570 of the active device integrated with a photodiode within the semiconductor layer 1530. In different embodiments, the contacts to the other regions of a composite device may be provided.

In yet another embodiment, each via in FIG. 15 may have an isolating film 1521 on the sidewalls. Conductive films 1522 may be deposited in each via to provide electrical contact to the respective regions of the semiconductor layer 1530. The features 1095 and 1096 serve to create good electrical (or Ohmic) contacts to the semiconductor regions as was described previously. The surface of the substrate 1010 may be covered with isolating film 1525. This film may be comprised of a dielectric material and may be different in composition from the feature 1521. In yet another embodiment, the vias 1011, 1012, and 1513 may be filled with a filler and planarized before processing the contact pads 570 as it was described in other embodiments above.

Another set of embodiments may describe structures outlined by discussion around FIG. 15 but comprising front-illuminated photodetector devices. For those skilled in the art it is obvious that for the front illuminated structure certain layers of opposite conductivity types may be swapped and modified otherwise using the powerful tools of multiple epitaxial layer deposition. A through via contacting the doped regions on the light impinging surface of the device structure may be formed to bringing the signals to the bottom surface of the device structure. In some embodiments, the sidewalls of those vias may be coated with insulator (dielectric). In yet other embodiments, the conductive layer may be aligned inside vias to connect features on the device surfaces.

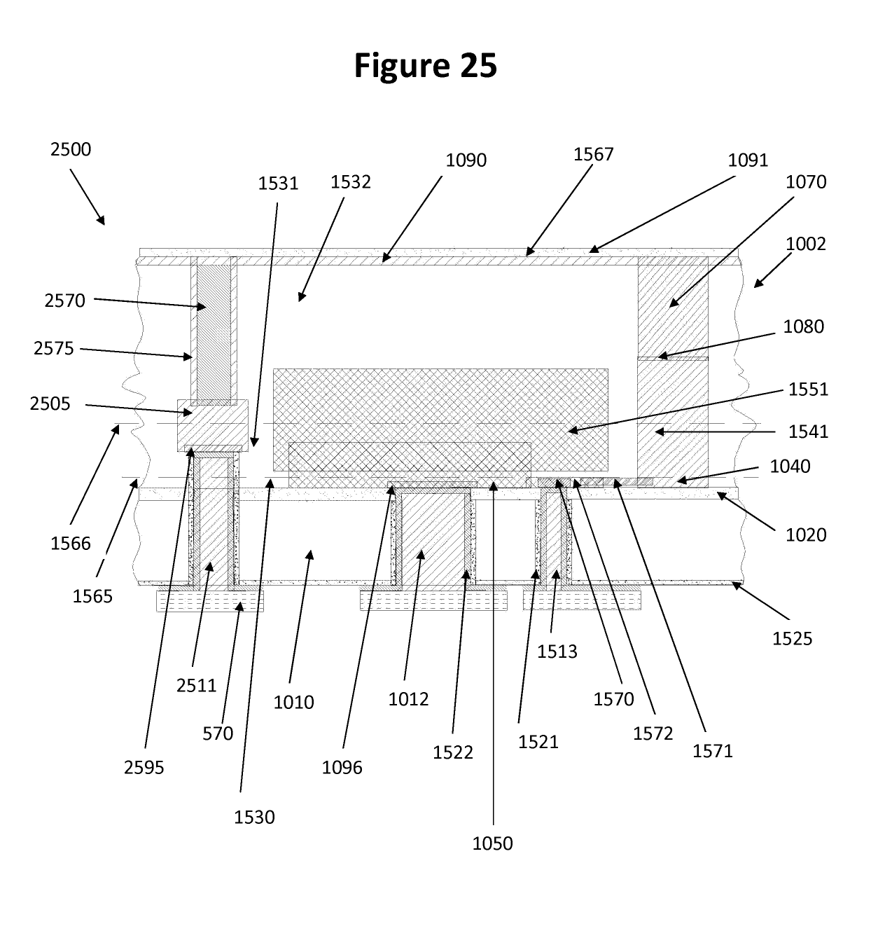

Taking advantage of the above discussion of embodiments that may comprise different epitaxial layers with various doped regions located within them, we proceed to FIG. 25, item 2500. In some embodiments, the structure of FIG. 25 may be formed on SOI wafer similar to item 1002. In another embodiment, two epitaxial layers 1531 and 1532 may be used to form the structure. In yet another embodiment, the doped regions 2505 of the first conductivity type and 1551 of the second conductivity type may be formed on the surface 1566 of the second epitaxial layer, which layer is proximate to the top surface 1567. Upon thermal treatment, the doped regions 2505 and 1551 expand within the first 1531 and second 1532 epitaxial layers. It is obvious for a skilled artesian that the number of epitaxially grown layers may be larger than two shown in FIG. 25. It is also obvious that, in some embodiments, more different doped regions may be formed within each epitaxial layer.

In another set of embodiments related to FIG. 25, through vias (trenches) 2570 may be etched from the top surface 1567 inside the epi layer 1532. In some embodiments, these vias may penetrate through the surface 1566, and may even reach the insulator layer 1020. In other embodiments, the sidewalls of the vias may be doped with the dopant 2575 of either a first or a second conductivity type. In other embodiments, those sidewalls may be coated with a layer of insulator material. In yet another embodiment, the vias may be backfilled with any material used in the industry as described in other embodiments of this invention.

Yet another set of embodiments described by FIG. 25 comprises the vias 2511 etched through the handling/support substrate 1010, insulator layer 1020, layers 1530 and 1531, and a portion of a doped region 2505. In some embodiments, these vias may penetrate more than one doped region of silicon layers, connecting them to each other. In yet another embodiment, the vias 2511 may not have contacts and pads 570 on top of the layer 1525. In other embodiments, the sidewalls of the vias 2511 may be coated with insulator 1521 and conductive layer 1522. In yet another embodiment, the region 2595 may be required to improve ohmic contact to the doped region 2505.

Yet another set of embodiments comprises a structure of FIG. 25 formed on semiconductor wafer bonded to a support substrate. In this case, item 1010 of FIG. 25 may comprise support substrate made of semiconductor, ceramic, insulator, or any other known in the industry material. In some embodiments, the device may be formed on semiconductor substrate with grown epitaxial layer, but no bonded support/handling substrate like item 1010 in FIG. 25 will be used. In this case, no insulator layer 1020 or other adhesive layer will be required either.

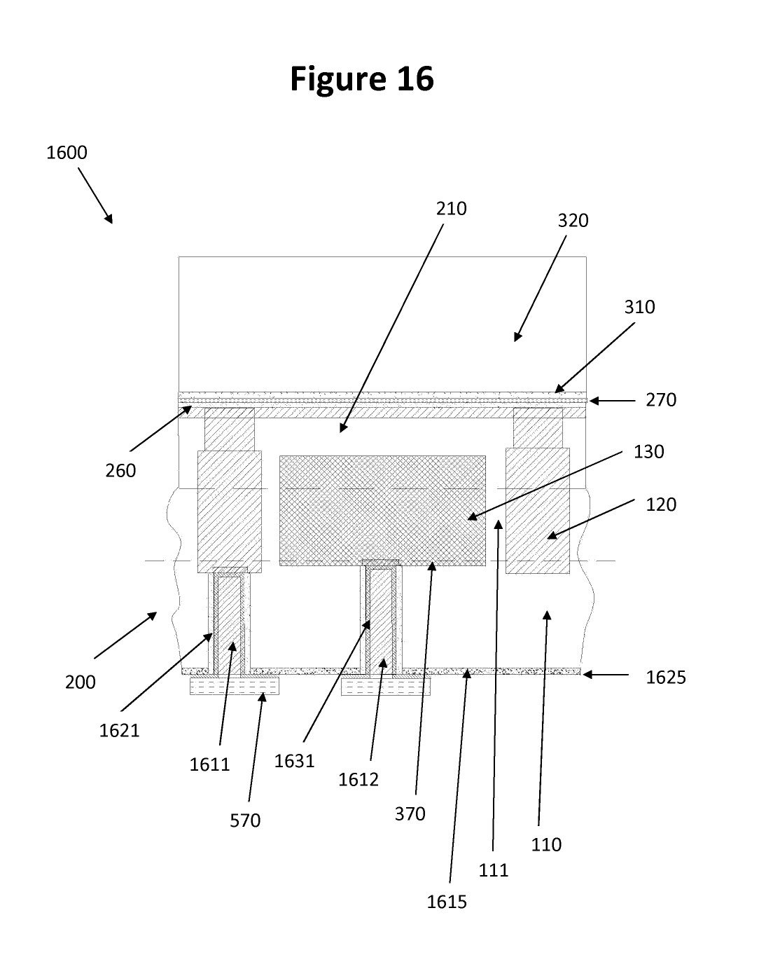

Proceeding to FIG. 16, item 1600, a series of embodiments for a photodiode array using a version of the process described with FIG. 3 is shown. The semiconductor material 110 may be made using a float zone process and may be thinned down to a different level than that shown by the dashed line 370, for example to a certain new level that does not expose doped regions 120 and 130. The semiconductor layer in this case may remain thick enough and no second substrate bonding step might be required for further processing. Alternatively, the thinning step may occur through the use of the TAIKO process previously described. For generality, there may exist numerous means known in the art that comprise acceptable scope within this inventive art.

The new surface after semiconductor thinning is shown as item 1615. The vias 1611 and 1612 are made in the semiconductor substrate to reach doped regions using reactive ion etch or other techniques known in the industry. In some embodiments, the sidewalls of vias may be coated with dielectric film 1621. The surface 1615 of the semiconductor layer is coated with a similar or different dielectric film 1625. The conductive film 1631 is deposited inside the via to contact the doped regions 120 and 130. The processing continues with deposition of contact pads 570 followed by the handling substrate 320 demounting. By way of non limiting example, the isolation structures in the embodiments described by FIG. 16 may be made with either dopant diffusion or vias (trenches). The combination of diffusion regions and vias may be applied similarly to what was shown in FIGS. 11 and 12. In another set of embodiments, the isolation regions between elements of the array may comprise sets of multiple diffusion regions or multiple isolation trenches. Yet another set of embodiments may provide isolation regions that enclose elements of the array completely. Alternatively, the isolation regions may comprise partial enclosure of each element of the array.

In yet another embodiment, the structure shown in FIG. 16 may be created as a version of the process described with FIG. 2. However, no handling substrate 320 may be required if TAIKO or another similar process was applied to thin the semiconductor material from the surface 1615 before making vias 1611 and 1612. In this embodiment, the semiconductor layer may have the active portion of the devices (photodiode junctions) created in an epitaxial grown layer 210 and the very top, light impinging surface may have a top film 260, which is a high uniformity dielectric film. In some of these embodiments the protective layer 270 with handling substrate 320 attached using bondable film 310 may not be required.

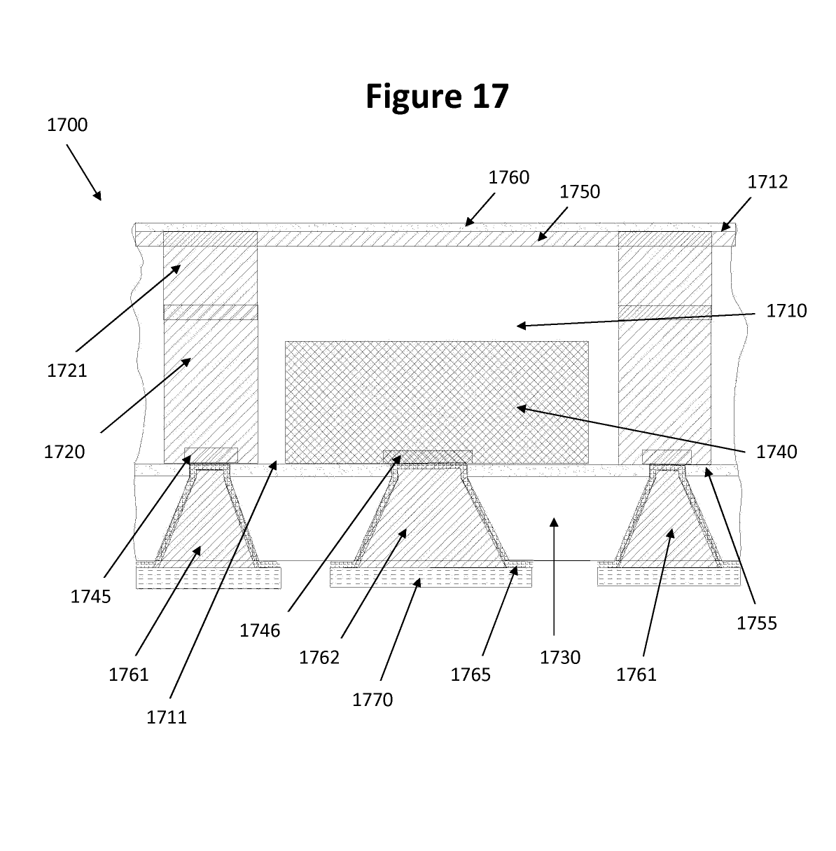

Proceeding to FIG. 17, another series of embodiments that result in photodetector arrays using the bonding innovations of this invention is depicted as item 1700. A device with similar structure and characteristics to the previously discussed flows may result from bonding where epitaxial depositions are not used.

Starting with a standard float zone semiconductor wafer 1710, which may in a non limiting example have the first conductivity type doping with a resistivity of roughly 500 ohm centimeters, the first surface 1711 of the starting material may be doped in regions defined by standard photolithographic steps. Feature 1720 and 1740 may be formed by these lithographic steps using doping of the first conductivity type and the second conductivity type, respectively. For example, without limitation, item 1720 could be formed by implanting a high level of Phosphorous into unmasked regions of the silicon wafer substrate. Thereafter, by way of non limiting example Boron could be implanted into different unmasked regions, 1740. By thermally diffusing over a long time at temperatures on the order of 1100 degrees centigrade the regions can be diffused into the bulk of the silicon. In some embodiments a second set of implant steps into the previously defined regions 1745 and 1746 could be performed to reestablish a high level of dopants to ensure good contact resistance. In other embodiments, the features 1745 and 1746 may be processed during later steps.

During the course of the thermal diffusion, in some embodiments, it is possible that oxidation will occur at a higher rate in the n-type doped regions than in others. After the doped regions 1740 and 1720 have been diffused and otherwise established, a bonding step may next be performed to the first surface 1711. A number of industry standard bonding processes may be used to affix a handling substrate to the semiconductor wafer 1710 which diffusions have been made in. The material of this first handling substrate could be a semiconductor or insulator material, and in a non limiting example a silicon substrate may be used. Since further thermal processing of high temperature and time will be used in this embodiment type, the bonding process may include for example a permanent bonding process with pressure and precise chemical cleaning process. Alternatively, the so-called anodic bonding process or any other bonding process may be applied. In some of these embodiments, such a process may require a very flat surface, and planarization of surface topography induced by the aforementioned differential oxidation may be required.

A semiconductor wafer 1710 bonded to the surface 1711 of a first handling substrate is then thinned from the other side, which creates the second surface 1712 of the active layer 1710 of a semiconductor device. The regions 1721 of the first conductivity type are deposited in the semiconductor layer 1710 from the surface 1712. These regions 1721 may be aligned with the regions 1720 on the first surface 1711 of the semiconductor layer 1710. High-temperature processing may follow this step to drive diffusions 1720 and 1721 into the semiconductor bulk and possibly to overlap them. A blanket deposition of the dopant of the first conductivity type 1750 is performed on the surface 1712 of the semiconductor layer. This may follow with the dopant activation and creation of the uniform dielectric film 1760.

To continue the process creating the structure shown in FIG. 17, the second handling substrate is attached to a semiconductor layer surface 1712. This may require intermediate layers similarly to the films 270 and 310 of FIGS. 2 and 3. In some embodiments, this second handling substrate may be dielectric, or glass for example. The first handling substrate may be removed at this point applying techniques that are known in the industry. By way of non-limiting example, the further processing may be described by FIGS. 4 through 8 to complete the structure shown in FIG. 17.

The isolation structures in the embodiments described by features 1720 and 1721 in FIG. 17 may be created with either dopant diffusion or vias (trenches). The combination of diffusion regions and vias may be applied similarly to shown with features 1110/1040 and 1210 in FIGS. 11 and 12, respectively. In some embodiments, the isolation regions between elements of the array may comprise a set of multiple combinations like 1720/1721 or multiple isolation trenches. Yet another set of embodiments may provide isolation regions that enclose elements of the array completely. Alternatively, the isolation regions may comprise partial enclosure of each element of the array. The final structure features the support substrate 1730, which may be semiconductor or isolating material. The isolating and adhesive layer 1755 may be comprised of one, two, or more films. In some embodiments, these films may be dielectric, for example glass. The vias 1761 and 1762 may be created to open contacts to the regions 1745 and 1746 of the semiconductor device. In some embodiments, the conductive layer 1765 may be deposit inside vias to create contacts to the regions 1745 and 1746. In yet another embodiment, the sidewalls of the vias may be coated with insulator film before conductive layer 1765 deposition. The vias may be backfilled with a standard filling material. The contact pads 1770 may be made applying any known industry technique. Without any limitations, there may be at least one via 1762 contacting each active region 1740 of the array. Also, there may be at least one via 1761 per array contacting the isolation structures 1720.

Yet another set of embodiments described by FIG. 17 may comprise isolation regions 1720 and 1721 formed with the dopant of the second conductivity type, which is the opposite polarity to that of the substrate 1710. The region 1750 may also be of the second conductivity type. The regions 1740 may be formed with the dopant of the first conductivity type having the concentration heavier than that of the substrate 1710.

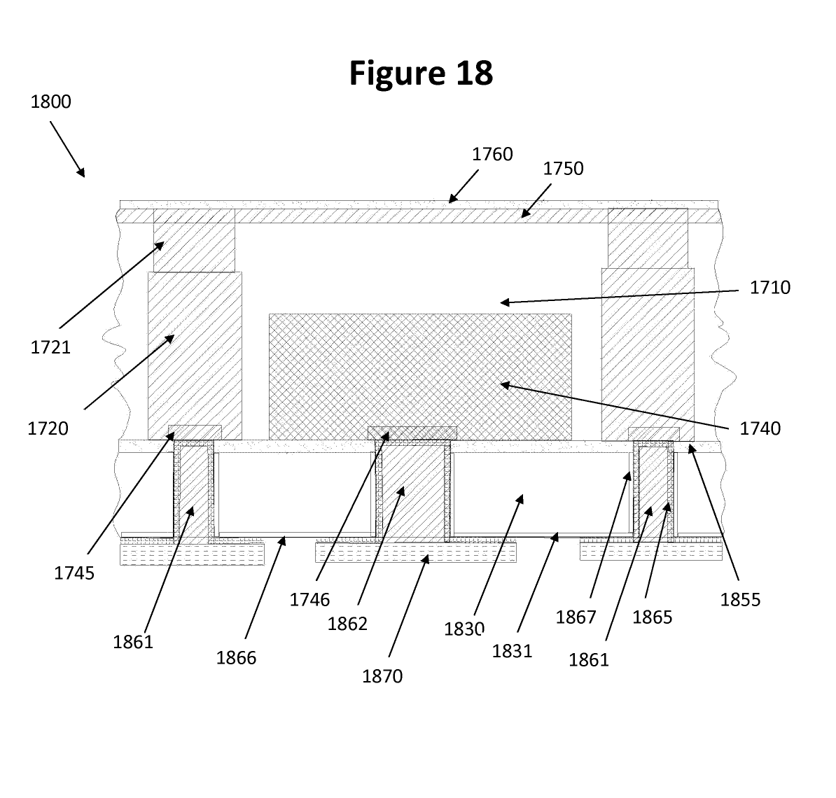

Yet another set of embodiments may be derived from the process based on the bulk wafer as a starting material, where no epitaxial deposition is required. In one of such embodiments, FIG. 18 item 1800, shows the structure that may combine semiconductor device layer 1710 with a permanently bonded semiconductor support substrate 1830. The bonding film 1855 may comprise any adhesion layer required to create reliable bonding between two semiconductor substrates 1710 and 1830. In some embodiments, this film 1855 may be isolating; alternatively, it may comprise a combination of isolating and conductive layers. The vias (trenches) 1861 and 1862 may be created by, for example, reactive ion etching technique to open semiconductor regions 1745 and 1746. In some embodiments, the sidewalls of the vias may be coated with isolation material (dielectric) 1867. The surface 1831 of the support substrate 1830 may be coated with a different isolating layer 1866. In yet another embodiment, the vias are coated with the conductive layer 1865. In some embodiments, these films (layers) 1865, 1866, and 1867 may be created using known in the industry techniques, some of them were described above. The vias may be filled with a filling material.

In some embodiments, the bonding pads shown as 1870 may be formed to allow bonding to the downstream electronics. In yet another embodiment, the top metal layer 1865 may be patterned and used for bonding purposes. Without any limitations, there may be at least one via 1862 contacting each active region 1740 of the array. Also, there may be at least one via 1861 per array contacting the isolation structures 1720. The isolation regions between elements of the array shown in FIG. 18 may comprise a set of multiple combinations like 1720/1721 or multiple isolation trenches. Yet another set of embodiments may provide isolation regions that enclose elements of the array completely. Alternatively, the isolation regions may comprise partial enclosure of each element of the array.

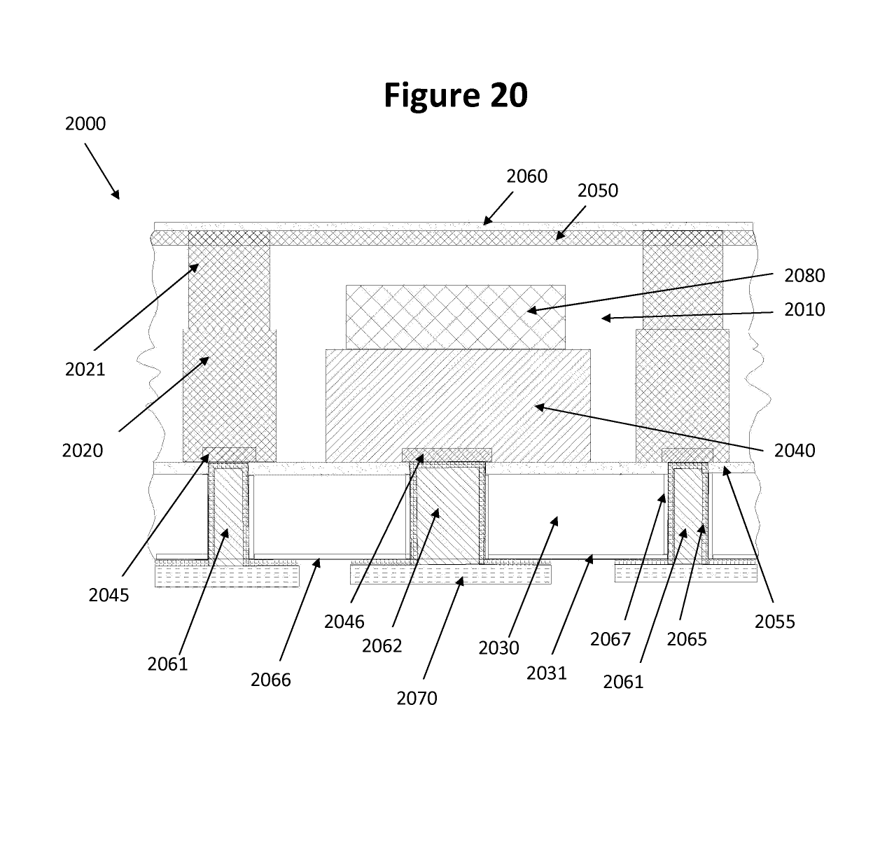

Proceeding to FIG. 20, another set of embodiments based of the structures with internal amplification may be described. Such structures include devices capable of multiplying a signal while absorbing the light quanta. For example, avalanche photodiode structures as photosensitive pixels may be discussed in one embodiment. In yet another embodiment, each photosensitive element of the array may contain a single Geiger-mode avalanche photodiode. In yet another embodiment, an array of multiple avalanche photodiodes connected in parallel and each working in a Geiger mode may comprise a single photosensitive element of the array. In this latter case, the term “silicon photomultiplier” may be used when referring to the structure of each element of the photosensitive array.

The structure of FIG. 20, item 2000, may comprise a semiconductor layer 2010 of the first conductivity type and having first and second surfaces, the first surface coated with the isolator (dielectric) film 2055 and the second surface coated with the isolator (dielectric) film 2060. In some embodiments, the films 2055 and 2060 may be made of the same material. In some embodiments, the structures 2020 and 2021 may comprise the isolation regions doped with the dopant of the first conductivity type with the concentration, heavier than the background concentration of the semiconductor layer 2010. By way of non limiting example, the regions 2020 and 2021 may overlap in the semiconductor bulk.

In other embodiments, isolation regions may be created with vias (trenches) or a combination of regions 2020 and vias, similarly to what has been described in many embodiments above. In yet another embodiments, blanket doping 2050 may be created proximate to the second surface of the semiconductor layer 2010 using dopant of the first conductivity type with concentration typically much heavier that the background concentration of the layer 2010. As a non-limiting example, the dopant concentration of the regions 2050, 2021, and 2020 may be higher than 10¹⁶ cm-3.

The doped region 2040 may be created using dopant of the second conductivity type with a concentration typically much heavier than that of the background concentration of the layer 2010. As a non-limiting example, the dopant concentration of the region 2040 may be higher than 10¹⁷ cm-3. The doped region 2080 may be created using dopant of the first conductivity type in a concentration, which may be heavier than the background concentration of the semiconductor layer 2010, but lower than that of the region 2040.

In some embodiments, this concentration may be targeted to provide avalanche multiplication of non-equilibrium carriers created by virtue of light absorption at a certain operating bias voltage. As a non-limiting example, the dopant concentration of the region 2080 may be higher than 10¹⁵ cm-3. In some embodiments, the regions 2080 and 2040 may overlap as it is shown in FIG. 20. In other embodiments, the regions 2080 and 2050 may not overlap and the spacing between their edges may be very different in different structures, spanning the range from as small as approximately 1 micron up to 200 microns or even larger. The width of this region is chosen by using the requirements of optimal absorption at operating wavelength as a guide.

In yet another embodiment, the vias 2061 and 2062 are created in the support substrate 2030 and isolating film 2055. Through these vias, the doped regions of the semiconductor layer 2010 are contacted. The support substrate 2030 could be made out of either semiconductor material or insulator (dielectric). By way of non-limiting example, the material of item 2030 may be silicon. In yet another embodiment, the whole structure may comprising a silicon on insulator wafer and its processing may be made in the way similar to the discussion about the embodiments above.

In yet another embodiment, the sidewalls of vias may be coated with insulator material or dielectric 2067. In other embodiments, a conductive layer 2065 comprising doped polysilicon or metal later may be deposited inside the vias and on top of the isolating films 2067 and 2066. The isolating film 2066 may cover the top surface 2031 of the support substrate 2030 and may be made from different material than the isolating film 2067. For those experienced in the art, there should be evident that any appropriate method may be used to create vias 2061 and 2062 in the substrate 2030, whether that substrate was isolator (dielectric) or semiconductor. In some embodiments, bonding pads 2070 may be formed to allow bonding to the downstream electronics.

In different embodiments, the structure shown in FIG. 20 may be manufactured using almost any method described in many embodiments above. For example, in some embodiments the starting material may comprise the semiconductor layer bonded to semiconductor support substrate (or silicon substrate in some particular examples) may be used. In yet another embodiment, the bulk semiconductor wafer bonded to any kind of a support substrate (semiconductor or isolator) may be used to process the structure. In many embodiments, the structure of FIG. 20 may be processed by growing epitaxial layer(s) on top of the semiconductor layer and patterning different epitaxial layers accordingly. In yet other embodiments, the bulk semiconductor layer may be used and processed as described in many embodiments above—no epitaxial layer growth may be required in this case.

Yet another set of embodiments may be derived for the structure, in which the active region enclosed by isolating regions 2020/2021 for each element of the array is composed of multiple micro-elements connected in parallel. As a non limiting example, each micro-element may have a similar structure to that of the whole active element 2040/2080. In other words, each micro-element may be thought of as an active pixel having the regions 2040 and 2080, although the dimensions of these regions may be much smaller than those of the element described in FIG. 20. The active pixels of the type 2040/2080 of all micro-elements of a single element of the array may be optically isolated from each other by special structures. In some embodiments, these isolating structures may be rather shallow trenches etched between micro-elements on the second surface (which may be the light-receiving surface) of the semiconductor layer 2010. Electrically, the micro-elements from each single element of the array may be connected in parallel.

Yet another set of embodiments may be derived from structures, in which each element of the photodetector array may comprise an array of micro-elements of different type than was discussed above. For example, each micro-element can be an NPN or JFET, or other type of transistors, wherein all micro-transistors of each single element of the array are connected in parallel. For those skilled in the art, many other embodiments can be derived from the structures described above and in FIG. 20.

In some embodiments, the isolation regions between elements of the array shown in FIG. 20 may comprise a set of multiple combinations like 2020/2021 or multiple isolation vias (trenches) penetrating from the top surface of the device structure, similar to ones discussed in different embodiments above. Yet another set of embodiments may provide isolation regions that enclose elements of the array completely. Alternatively, the isolation regions may comprise partial enclosure of each element of the array.

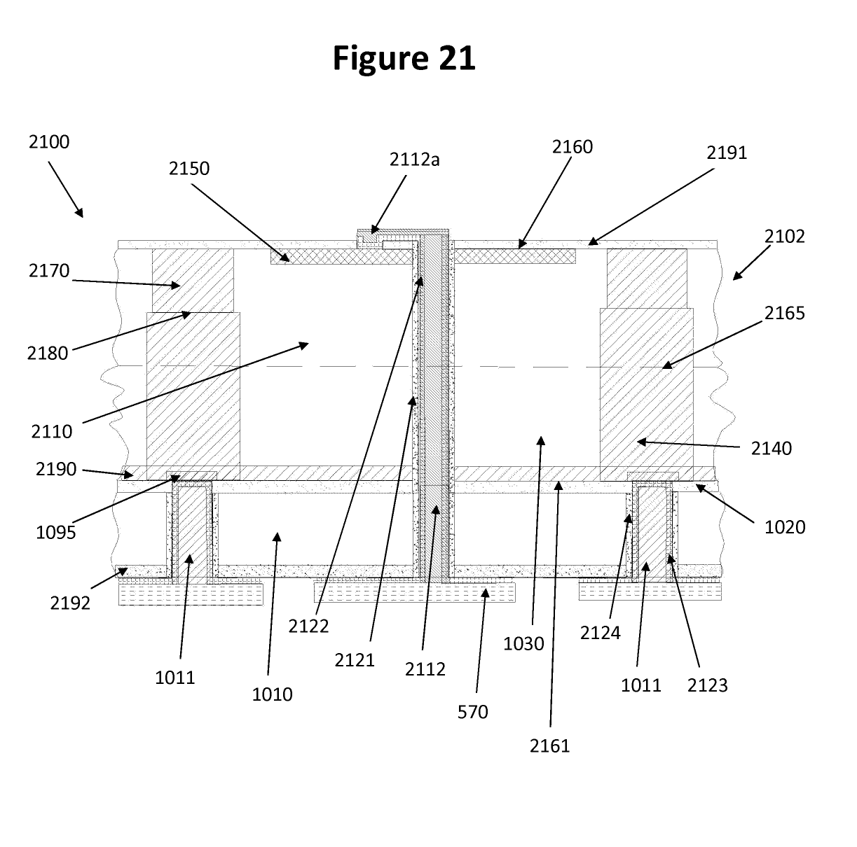

Proceeding to FIG. 21, item 2100 yet another set of embodiments may be derived now based on front-illuminated structures. To obtain a device of this type, a starting material like a semiconductor on insulator substrate may be used. The starting material may be similar to those described in other embodiments above. This material, item 2102, may have a handling substrate 1010 and an insulator layer 1020 that separates but supports the top most layer 1030. The surface item 2161 separates the semiconductor layer 1030 and insulator layer 1020. However, the bottom portion of the layer 1030, which is proximate to the surface 2161, may comprise higher dopant concentration of the same conductivity type as the bulk of the layer 1030. There may be many ways to create this starting material structure. By way of a non-limiting example, the low dopant concentration layer 1030 way be deposited or grown on the top of the high dopant concentration layer 2190. The top surface of the layer 1030 is represented by the dashed line, item 2165. In some embodiments this top most layer may comprise silicon where that layer has been doped with the dopant of the first conductivity type and comprises a thickness of approximately 1 micron. In a manner that is similar to the processing shown in FIG. 10, regions of the top silicon material layer 1030 may have regions that are masked off by photo lithography steps and then doped with the first conductivity type regions 2140 (in the concentration heavier than the background concentration of the layer 1030).

This composite substrate 1010/1030 having the layer 2190 may then be processed with epitaxial processing steps as discussed in the embodiments above to obtain a new bulk, item 2110, with a new top surface shown as item 2160. As previously discussed, during the processing of the epitaxial layer, which may occur at temperatures of 1000 degrees centigrade or more, the dopant regions that were formed into the starting layer 1030 will diffuse over the processing time. It may be apparent to one skilled in the arts that there may be numerous manners in which the epitaxial process may be performed.

In some embodiments, to continue with the processing, the new top surface 2160 of the device layer may now be subjected to lithography processes to further define regions of the isolation 2170. For example, the first conductivity type regions of dopant 2170 with the concentration heavier than the background concentration of the layer 2110 may be formed to align with the regions item 2140 by lithographic processing. With further processing, in some embodiments, the various dopant regions may be diffused under thermal processing to diffuse into neighboring regions of the device layer 1030. In some embodiments, the diffusion may proceed to cause the top and bottom isolation features to overlap each other as shown in FIG. 21 by the arrow at item 2180. The isolation regions between elements of the array shown in FIG. 21 may comprise a set of multiple combinations like 2140/2170/2180 or multiple isolation vias (trenches) penetrating from the top surface 2160 of the device structure, similar to ones discussed in different embodiments above. Yet another set of embodiments may provide isolation regions that enclose elements of the array completely. Alternatively, the isolation regions may comprise partial enclosure of each element of the array.

In an example embodiment, the top surface 2160 may be patterned and the anode/cathode regions 2150 of the second conductivity type may be formed, with the concentration heavier than the background concentration of the item 2110. Thermal processing may then be used to activate the dopants. In some embodiments, a thin oxide film item 2191 may be formed during this activation processing. Alternatively, a thin oxide film may be formed in a subsequent growth or deposition step to form such a film. It may be obvious to one skilled in the arts that there could be numerous acceptable layers consistent with the optical needs of the device that could be formed here and that the material, thickness and other aspects of the film may be varied in a manner that is consistent with the inventive art herein.

In some embodiments, the vias 2112 may be etched through the layers 2110, 1030, 1020, and penetrate to a certain depth into the substrate layer 1010. The sidewalls of the vias 2112 may be coated with the film of insulator 2121. In one embodiment, a conductive film 2122 may be deposited over the insulator 2121. In yet another embodiment, the vias may be filled with a conductive filler, 2121a. By way of a non limiting example, doped polysilicon may be used as a filler. Both the conductive film 2122 and filler 2112a may contact the doped regions 2150 through the openings in the isolation film 2191. There may be at least one via 2112 per element of the array.

In some embodiments, the resulting surface could be bonded temporarily to a new handling substrate and processed in a manner described in the initial embodiment discussion starting from FIG. 5 or outlined with the discussion of FIG. 10. In some embodiments, the resulting substrate comprised of a handling part 1010, an insulator layer 1020 and a formed device later of some embodiment thereon, may be thinned to a particular overall device thickness as required for particular applications, During thinning the vias 2112 are intercepted exposing the conductive filler and conductive film 2122. It may be apparent to one skilled in the arts that the vias 2112 may also be formed after thinning of the substrate.

After thinning, the back layer of the substrate that remains may be processed by a technique to create vias 1011, which penetrate the handling substrate 1010 and the insulator layer 1020. As a non-limiting example, there may be at least one via 1011 per whole array. The via 1011 may then allow electrical connection to the doped regions of the initially formed layer, for example items 2140 and 2190 through the ending features 1095. It may also be apparent to a skilled artisan, that in an equivalent manner as described for vias 2112 that vias 1011 may also be formed at the same time going through the entire substrate and formed layers thereon. Any of the standard methods of forming a thru substrate contact via would define embodiments consistent with the inventive art herein. As well, as an example, the processing of thru vias was described to occur after the handling region of the substrate 1010 was thinned.

Other embodiments may occur with processing of the vias occurring before the substrate is subjected to thinning steps. Still further embodiments may be possible where the via hole is processed before thinning but not filled until after the substrate has been thinned by one of various means. It may be apparent to one skilled in the arts that any method of defining a contact through a substrate to an active layer defines embodiments consistent with the art herein. The conductive layer 2123 may be deposited on the sidewalls and inside vias 1011 to provide electrical connections to the semiconductor regions 1095. In the case where the substrate 1010 was a semiconductor, the isolating layer 2124 may be deposited on the sidewalls of the vias prior to a conductive film 2123 deposition. In some embodiments, vias 1011 may be filled with a standard filler, which may be either conductive or non-conductive material. The bottom surface of the overall structure may be coated with insulator film 2192, then contacts opened appropriately and bonding pads 570 formed applying any known in the industry method.

Yet another set of embodiments may be derived from the structure similar to depicted in FIG. 21 but without a support substrate 1010. In some embodiments of this case, the composite semiconductor layer 1030/2190 may be thick enough to support the overall integrity of the device. By way of a non limiting example, the total thickness of the layer 1030/2190 may be less than 150 micron. in other embodiments this thickness may be more than 150 micron.

Yet another set of embodiments described by FIG. 21 may comprise isolation regions 2140 and 2170 formed with the dopant of the second conductivity type, which is the opposite polarity to that of the substrate 1030 and layer 2110. The region 2190 may also be of the second conductivity type. The regions 2150 may be formed with the dopant of the first conductivity type having the concentration heavier than that of the layer 2110.

In multiple other embodiments, other front-illuminated, thin photosensitive devices may be described based on the basic features outlined in different embodiments above and using the same or similar approach discussed in FIG. 21. Some of these structures were outlined above, but for a skilled in the art it is obvious that other embodiments may be designed and considered as the part of the current invention based on the main ideas discussed herein.

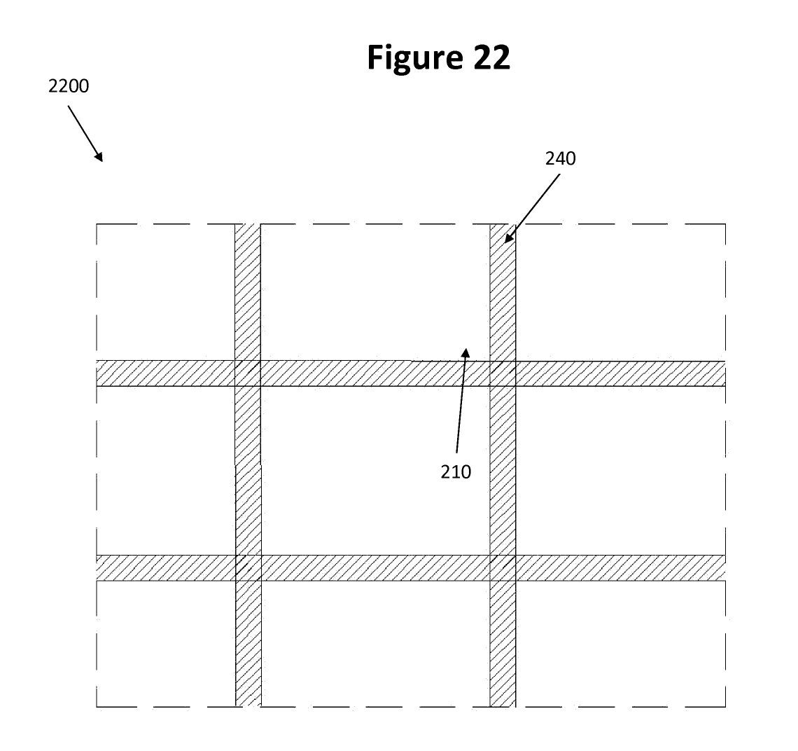

FIG. 22, item 2200 is a non limiting example of how the final structure may be viewed from the light entering side of the backside illuminated array. Regions 240 isolate elements of the photodetector array from each other forming an array of equal-size, rectangular-shaped elements. Such arrays may be linear arrays or two dimensional arrays. In other embodiments the shape of the pixels may be a square or different polygon. In still further embodiments the shape of the pixels may have rounded corners or have curved edges defining for example circles, ovals or features similar to these. In still other embodiments, the size of the array elements may not necessarily be equal. The regions 210 comprise the active regions of elements of the array, where the impinging light quanta are absorbed by the semiconductor and converted into non-equilibrium carries.

The various embodiments of photodetector arrays that may be built from substrates with bonded layers or with epitaxial growth as has been mentioned herein may be assembled into sub-systems that utilize the photodetector arrays and therefore create new embodiments of the invention herein. In an embodiment of this invention of this type an imaging system for medical imaging or other applications includes a radiation sensitive detector with a pixellated scintillator array optically coupled to the isolated pixels semiconductor photo-sensitive device. A plurality of isolated pixels in a semiconductor photodetector array, where the array of pixels has been formed by one of the embodiments described herein is connected to the readout electronics either by directly contacting the pre-amplifiers or via routings through the support substrate(s). The connection to the readout electronics may be provided on either side of the isolated pixels primary photodetector array. By way of non limiting example, the support substrate(s) may be ceramic material, semiconductor, or other known in the art material.

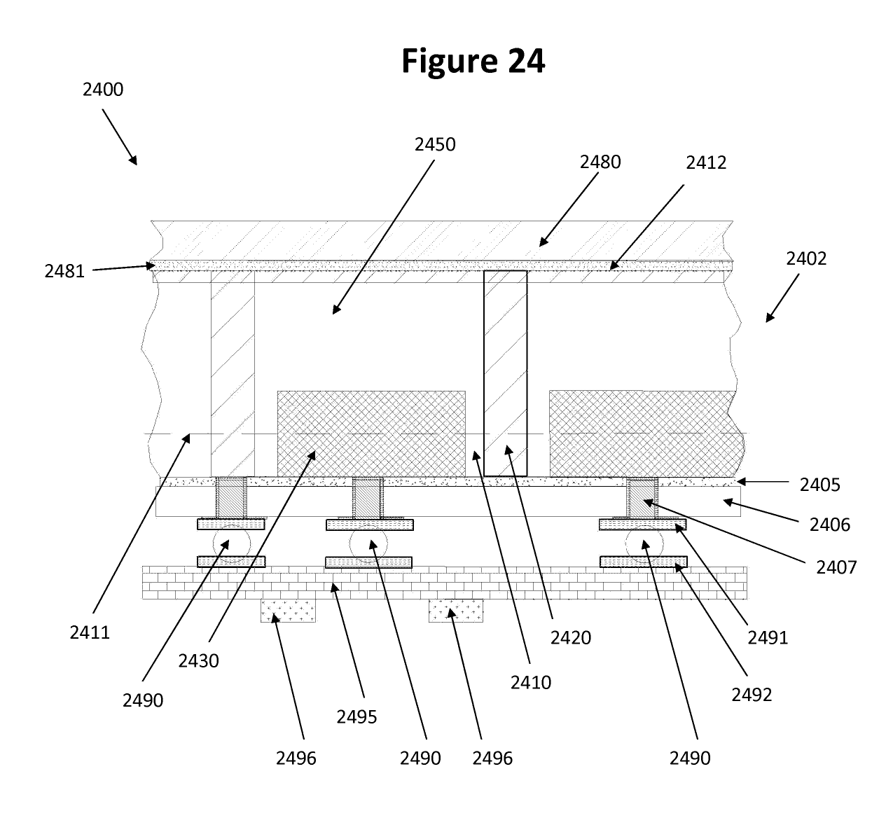

As an example of such embodiments, FIG. 24, item 2400 depicts the photodiode array 2402 of one of the embodiments described above. In some embodiments, an array may be formed in a substrate comprising a semiconductor layer 2410 of a first conductivity type and epitaxial grown layer 2450 of the same conductivity. The item 2411 shows the surface of the semiconductor layer 2410 upon which the epitaxial layer 2450 was grown. In some embodiments, the doped regions 2430 of the second conductivity type propagate within the epitaxial layer 2450 and semiconductor layer 2410. In some embodiments, the isolation regions 2420 may be doped regions of the first conductivity type, in other embodiments, they may be the combinations of doped regions and vias (trenches), as has been described in many embodiments above. In some embodiments, these isolation regions 2420 may span the semiconductor layer 2410 and epitaxial layer 2450. The vias 2407, made in a first support substrate 2406 and insulator layer 2405, allow for electrical connection of each pixel of the array 2402 to the downstream electronics. In some embodiments, a plurality of pixels of an array 2402 contact the pre-amplifiers 2496 on the second support substrate 2495 through metal pads 2491, 2492 and conductive bumps 2490. As noted in the previous paragraph, the second support substrate may be ceramic material, semiconductor, or other known in the art material. In some embodiments, the top surface 2412 of the layer 2450 may be bonded to the scintillator material 2480. In other embodiments, the adhesive material 2481 may be used for bonding purposes.

Another embodiment derives from the inventive art herein where the isolated pixels of the primary photodetector are connected individually to input nodes of readout electronics of an imaging system. The isolation area between pixels may be connected to a different electrode of the readout electronics.

In accordance with another embodiment of the present invention, the isolated pixels of the semiconductor array are separately connected to readout electronics either by directly contacting a pre-amplifier or via routing through the support substrate(s). Direct contact to a preamplifier may derive from the embodiments where a layer of the active device that is formed is comprised of various active and passive components forming a preamplifier circuit within the device layer of the produced device. In some of these embodiments each isolated pixel of the photodetector that is a part of imaging system can contain an integrated pre-amplifier.

Yet another embodiment of the present invention implies use of the primary photodetector array of the embodiments described herein and the whole detector system that incorporate the said primary photodetector arrays in applications like Computed Tomography (CT), Positron Emission Tomography (PET), Single Photon Emission Computing Tomography (SPECT). Optical Tomography (OT), Optical Coherent Tomography (OCT) and the like.

In the various embodiments disclosed herein, generally a single diode of each embodiment is shown in detail, though in an array, such diode structure will be replicated in one or two dimensions. By way of but one example, referring to FIG. 2, the right side regions 240, 220 and 120 for the diode structure shown, are the corresponding left side regions of the same diode structure to the right of the one shown, etc. Again referring to FIG. 2, as an example in an array, regions 130, 230 and 210 are interspersed within an array of regions 240, 220 and 120.

It may be apparent to one skilled in the art that while certain embodiments have been described with specific dopant types identified that devices may be performed where different polarity of dopant type species and substrate characteristics may be used within the scope of this invention.

While the invention has been described in conjunction with specific embodiments, it is evident that many alternatives, modifications and variations will be apparent to those skilled in the art in light of the foregoing description. Accordingly, this description is intended to embrace all such alternatives, modifications and variations as fall within its spirit and scope.

1. A photodiode comprising:
an active region of semiconductor of a first conductivity type having a top surface, a bottom surface and side surfaces;
a first semiconductor layer on the top surface of the active region of semiconductor, the first semiconductor layer being of the first conductivity type and more highly doped than the semiconductor;
a first plurality of regions of the first conductivity type with concentration heavier than that of the semiconductor forming a grid on the top surface of the active region of semiconductor;
a plurality of regions of a second conductivity type interspersed within the first plurality of regions of the first conductivity type and not touching the first semiconductor layer;
a second plurality of regions of the first conductivity type on the bottom surface of the active region of semiconductor, with a concentration heavier than that of the semiconductor and being aligned with the first plurality of regions of the first conductivity type;
a substrate layer bonded to the plurality of regions of the second conductivity type and the second plurality of regions of the first conductivity type;
a first metal region in electrical contact with the second plurality of regions of the first conductivity type through the substrate layer; and,
a second metal region in electrical contact with the plurality of regions of the second conductivity type through the substrate layer.

2. A photodiode array comprising:
a plurality of photodiodes, each in accordance with claim 1, the photodiodes being disposed to form a two-dimensional photodiode array.

3. A photodiode device in accordance with claim 1:
wherein the region between the first semiconductor layer and the plurality of regions of the second conductivity type is comprised of epitaxial semiconductor.

4. A photodiode comprising:
a region of semiconductor of a first conductivity type having anode and cathode regions formed within and comprising a photodiode;
wherein a semiconductor region between the anode and cathode is comprised of epitaxial semiconductor;
wherein at least one of the anode and cathode extends both inside the epitaxial semiconductor layer and outside that layer;
and the perimeter of said semiconductor region is comprised, at least in part, of an isolating region where the isolating region spans from the cathode region to at least the anode region; while not necessarily completely enclosing either the cathode region or the anode region.

5. A photodiode in accordance with claim 4:
wherein at least a portion of each of the anode and cathode regions are located vertically relative to each other relative to a horizontal surface that photons impinge upon.

6. A photodiode in accordance with claim 4:
wherein the anode or cathode region which extends both inside the epitaxial semiconductor layer and outside that layer, being of a first conductivity type, abuts neighboring regions of a second conductivity type along the interface of the epitaxial semiconductor layer and said region outside the epitaxial semiconductor layer.

7. A photodiode array comprising:
a plurality of photodiodes, each in accordance with claim 4, the photodiodes being disposed to form a two-dimensional photodiode array.

8. A back-illuminated photodiode array comprising:
a semiconductor substrate having a conductivity of a first type with a first concentration and with a first and second surface;
an epitaxially grown layer, having a conductivity of the first type with a second concentration, upon the first surface and extending to a third surface;
a plurality of the first regions of a first conductivity type with a concentration heavier than that of the epitaxial layer and semiconductor substrate, and extending from a third surface of the epitaxial layer to within the epitaxial layer;
a plurality of second regions of a first conductivity type with a concentration heavier than that of the epitaxial layer and semiconductor substrate, and extending from a first surface of the semiconductor substrate to within both the substrate and epitaxial layer;
a plurality of isolated regions of a second conductivity type interspersed within the second regions of the first conductivity type, and extending from the first surface of the semiconductor substrate to within that substrate and epitaxial layer, but not reaching the third surface;
a region of a first conductivity type with a concentration heavier than that of the epitaxial layer, on a third surface of the epitaxial layer; and
at least a single electrical contact through a via to at least a portion of the semiconductor substrate to one of the regions of a second conductivity type.

9. A front-illuminated photodiode array comprising:
a semiconductor substrate having a conductivity of a first type with a first concentration and with a first and second surface;
an epitaxially grown layer having a conductivity of the first type with a second concentration, upon the first surface and extending to a third surface;
a plurality of first regions of a first conductivity type with a concentration heavier than the first and second concentrations extending from the third surface of the epitaxial layer to within the epitaxial layer;
a plurality of the second regions of a first conductivity type with a concentration heavier than the first and second concentrations, extending from the first surface of the semiconductor substrate to within the epitaxial layer and semiconductor substrate;
a plurality of isolated regions of a second conductivity type interspersed within the first regions of the first conductivity type, and extending from the third surface of the epitaxial layer to within the epitaxial layer;
a layer within the semiconductor substrate having the conductivity of the first type with the concentration heavier than the first and second concentrations; wherein this layer may extend partially through the first surface into the epitaxial layer;
at least a single electrical contact through a via to at least a portion of the semiconductor substrate in the region of the first conductivity type.

10. A back-illuminated photodiode array comprising:
a semiconductor on insulator (SOI) substrate with a first and second surface and an insulator layer in between;
wherein a portion of the said SOI substrate between the insulator layer and the first surface is a first semiconductor layer having a first conductivity type and a first concentration;
an epitaxially grown layer having a conductivity of a first type with a second concentration, upon the first surface and extending to a third surface;
a plurality of first regions of a first conductivity type with a concentration heavier than the first and second concentrations, extending from the third surface of the epitaxial layer to within the epitaxial layer;
a plurality of second regions having a first conductivity type with the concentration heavier that the first and second concentrations, and extending from the first surface of the SOI substrate to within the first semiconductor layer and epitaxial layer;
a plurality of isolated regions of a second conductivity type interspersed within the second regions of the first conductivity type, and extending from the first surface of the SOI substrate to within the first semiconductor layer and epitaxial layer, but not reaching the third surface;
a region of a first conductivity type with concentration heavier than the second concentration on a third surface of the epitaxial layer; and,
at least a single electrical contact comprising a via through the said insulator layer between the first and second surfaces of the semiconductor on insulator substrate.

11. A back-illuminated photodiode array comprising:
a semiconductor substrate having conductivity of a first type with a first concentration, with a first and second surface;
an epitaxial layer, having the conductivity of the first type with a second concentration, upon the first surface and extending to a third surface;
a plurality of first regions of a first conductivity type with concentration heavier than the first and second concentrations, and extending from a third surface of the epitaxial layer to within the epitaxial layer;
a plurality of second regions of a first conductivity type with concentration heavier than the first and second concentrations, and extending from the first surface of the semiconductor substrate to within the semiconductor substrate and epitaxial layer;
a plurality of isolated regions of a second conductivity type interspersed within the second regions of the first conductivity type, and extending from the first surface of the semiconductor substrate to within the semiconductor substrate and epitaxial layer;
a region of a first conductivity type with concentration heavier that the first concentration, on the third surface of the epitaxial layer; and,
at least a single via in at least a portion of the epitaxial layer.

12. A method of forming a back illuminated photo diode array comprising:
processing a semiconductor substrate of the first conductivity type that has an upper surface upon which epitaxial layers may be grown by coating the substrate with a photoresist layer;
exposing the photoresist layer to a lithographic process to define regions that are coated by photoresist and regions that are not coated by photoresist;
doping the non coated regions with a first or second conductivity type into the substrate;
stripping the photoresist regions that remain on the substrate and cleaning the substrate;
growing an epitaxial layer of the first or second conductivity type upon the doped and undoped regions of the upper surface of said semiconductor substrate to create a new top surface;
further processing the substrate to result in a photodiode being formed thereon.

13. A backlit photodiode array with embedded amplification comprising:
a semiconductor substrate having the conductivity of a first type with a first concentration and with a first and second surface;
at least one epitaxially grown layer upon the first surface and extending to a third surface and having a conductivity of the first type;
a plurality of first regions of a first conductivity type with a concentration heavier than that of each epitaxial layer and semiconductor substrate, and extending from the third surface to within the epitaxial layer(s);
a plurality of second regions of a first conductivity type extending from a first surface of the semiconductor substrate to within both the semiconductor substrate and epitaxial layer(s);
a plurality of first isolated regions of a second conductivity type interspersed within the second regions of the first conductivity type, and extending from the first surface of the semiconductor substrate to within that semiconductor substrate and epitaxial layer(s), but not reaching the third surface;
a region of a first conductivity type with a concentration heavier than that of the epitaxial layer(s), on the third surface(s) of the epitaxial layer(s);
a plurality of second isolated regions of a second conductivity type interspersed within the second regions of the first conductivity type and formed inside at least one epitaxial layer wherein at least a portion of the plurality of the second regions of the second conductivity type have diffusion partially overlapping with at least a portion of the plurality of the first regions of the second conductivity type; and,
at least a single electrical contact through a via to one of the first regions of the second conductivity type to the second surface of the semiconductor.

14. A photodiode array of claim 13 having:
at least a single electrical contact through a via to at least one of the second regions of the first conductivity type.

15. A back-illuminated photodiode array with embedded amplification comprising:
a semiconductor on insulator (SOI) substrate with a first and second surface and an insulator layer in between;
wherein the portion of the SOI substrate between the insulator layer and the first surface is a first semiconductor layer having a first conductivity type and a first concentration;
at least one epitaxially grown layer upon the first surface and extending to a third surface, the epitaxial layer(s) having a conductivity of the first or second type;
a plurality of first regions of a first conductivity type with a concentration heavier than the first concentration and epitaxial layer(s) concentrations, extending from a third surface to within the epitaxial layer(s);
a plurality of second regions having a first type conductivity with the concentration heavier than the first and epitaxial layer(s) concentrations, and extending from the first surface of the semiconductor substrate to within the first semiconductor layer and epitaxial layer(s);
a plurality of first isolated regions of a second conductivity type interspersed within the second regions of the first conductivity type, and extending from the first surface of the semiconductor substrate to within the first semiconductor layer and epitaxial layer(s), but not reaching the third surface;
a region of a first conductivity type with concentration heavier that the second concentration on a third surface of the epitaxial layer(s);
a plurality of second isolated regions of a second conductivity type interspersed within the second regions of the first conductivity type and formed inside at least one epitaxial layer wherein at least a portion of the plurality of second regions of the second conductivity type have diffusion partially overlapping with at least a portion of the plurality of first regions of the second conductivity type; and,
at least a single electrical contact comprising a via through the insulator layer between the first and second surfaces of the semiconductor on insulator substrate.

16. A back illuminated photodiode array with embedded amplification comprising:
a semiconductor substrate having a conductivity of the first type with a first concentration and with a first and second surface; the second surface of the said semiconductor substrate being bonded to an insulator substrate;
at least one epitaxially grown layer upon the first surface and extending to a third surface, each layer having the conductivity of the first or second type;
a plurality of first regions of a first conductivity type with a concentration heavier than that of the epitaxial layer(s) and semiconductor substrate, and extending from a third surface to within the epitaxial layer(s);
a plurality of second regions of a first conductivity type having a concentration heavier than that of the epitaxial layer(s) and semiconductor substrate, and extending from a first surface of the semiconductor substrate to within both the semiconductor substrate and epitaxial layer(s);
a plurality of first isolated regions of a second conductivity type interspersed within the second regions of a first conductivity type, and extending from the first surface of the semiconductor substrate to within that semiconductor substrate and epitaxial layer(s), but not reaching the third surface;
a region of a first conductivity type with a concentration heavier than that of the epitaxial layer(s), on a third surface of the epitaxial layer(s);
a plurality of second isolated regions of a second conductivity type interspersed within the second regions of the first conductivity type and formed inside at least one epitaxial layer wherein at least a portion of the plurality of second regions of the second conductivity type have diffusion partially overlapping with at least a portion of the plurality of first regions of the second conductivity type; and,
at least a single electrical contact through a via in the insulator substrate to at least one the first regions of the second conductivity type to the second surface of the semiconductor substrate.

17. A back-illuminated photodiode array with internal amplification comprising:
a semiconductor substrate with a first and second surface and a support substrate bonded to the second surface of the semiconductor substrate;
wherein the said semiconductor substrate has a first conductivity type and a first concentration;
at least one epitaxially grown layer upon the first surface and extending to a third surface and having a conductivity of the first or second type;
a plurality of first regions having the first conductivity type with a concentration heavier than the first concentration and epitaxial layer(s) concentrations, extending from a third surface of the epitaxial layer(s) to within the epitaxial layer(s);
a plurality of second regions having a first type conductivity with a concentration heavier that the first concentration and epitaxial layer(s) concentrations, and extending from a first surface of the semiconductor substrate to within the first semiconductor layer and epitaxial layer(s);
a plurality of first isolated regions of a second conductivity type, interspersed within the second regions of a first conductivity type, and extending from the first surface of the semiconductor substrate to within the semiconductor substrate and epitaxial layer(s), but not reaching the third surface;
a region of a first conductivity type with concentration heavier than the epitaxial layer(s) concentration on a third surface of the epitaxial layer;
a plurality of second isolated regions of the first conductivity type interspersed within the second regions of a first conductivity type and formed in epitaxial layer(s) between the third surface and first isolated regions of the second conductivity type; the concentration of the second isolated regions of the first conductivity type being heavier than that of the epitaxial layer(s) but lower than that of the pluralities of the first and second regions of the first conductivity type; and,
at least a single electrical contact comprising a via through the support substrate.

18. A composite ultrathin device comprising:
a semiconductor substrate having the conductivity of a first type with a first concentration and with a first and second surface;
at least one epitaxially grown layer upon the first surface and extending to a third surface, each layer having specific type of conductivity;
a plurality of first doped regions with a concentration heavier than that of the epitaxial layer closest to the first surface of the semiconductor substrate, and extending from this first surface to within both the epitaxial layer(s) and semiconductor substrate underneath the first surface;
a plurality of second doped regions with concentration heavier than that of the epitaxial layer closest to the third surface, and extending from the third surface of the epitaxial layer(s) to within epitaxial layer(s);
a plurality of first vias penetrating from the third surface to within the epitaxial layer;
a plurality of third doped regions interspersed within the first doped regions and extending from the first surface of the semiconductor substrate to within that semiconductor substrate and epitaxial layer(s), but not reaching the third surface;
fourth doped regions having concentration heavier than that of the epitaxial layer closest to the third surface, wherein the forth doped regions are proximate to the third surface of the epitaxial layer;
a plurality of at least partially isolated regions interspersed within the first and second doped regions and formed inside one or several of the epitaxial layers; each of the at least partially isolated regions having a part of the partially isolated region with a concentration heavier than that of the epitaxial layer in which it is embedded;
wherein at least one region with a concentration heavier than that of the epitaxial layer overlaps at least partially with any of the first, second, third, or fourth doped regions;
a plurality of second vias through at least one doped semiconductor region;
at least a single electrical contact through a third via in at least a portion of the semiconductor substrate to one of the doped regions at the first surface of the semiconductor substrate; and,
at least a single conductive layer deposited within at least the third via.

19. A composite ultrathin device comprising:
a semiconductor on insulator (SOI) substrate with a first and second surface and an insulator layer in between;
wherein the portion of the SOI substrate between the insulator layer and the first surface is a first semiconductor layer having a first concentration;
at least one epitaxially grown layer upon the first surface and extending to a third surface, each layer having specific type of conductivity;
a plurality of first doped regions with a concentration heavier than that of the epitaxial layer closest to the first surface of the first semiconductor layer, and extending from this first surface to within both the epitaxial layer(s) and first semiconductor layer underneath the first surface;
a plurality of second doped regions with concentration heavier than that of the epitaxial layer closest to the third surface, and extending from the third surface of the epitaxial layer(s) to within epitaxial layer(s);
a plurality of first vias penetrating from the third surface to within the epitaxial layer;
a plurality of third doped regions interspersed within the first doped regions and extending from the first surface of the first semiconductor layer to within that first semiconductor layer and epitaxial layer(s), but not reaching the third surface;
fourth doped regions having concentration heavier than that of the epitaxial layer closest to the third surface, wherein the forth doped regions are proximate to the third surface of the epitaxial layer;
a plurality of at least partially isolated regions interspersed within the first and second doped regions and formed inside one or several of the epitaxial layers; each of the at least partially isolated regions having a part of the partially isolated region with a concentration heavier than that of the epitaxial layer in which it is embedded;
wherein at least one region with a concentration heavier than that of the epitaxial layer overlaps at least partially with any of the first, second, third, or fourth doped regions;
a plurality of second vias through at least one doped semiconductor region;
at least a single electrical contact through a third via in the insulator layer in between the first and second surfaces of SOI substrate, to one of the doped regions at the first surface of the semiconductor substrate; and,
at least a single conductive layer deposited within at least the third via.

20. A radiation detection system comprising:
a photo-sensitive device having multiple photo-sensitive elements arrayed upon a substrate having at least a single semiconductor layer and support layer, and at least one epitaxial layer grown upon patterned doped regions in at least a portion of the semiconductor layer, also having isolation regions surrounding the periphery of each of the multiple photo-sensitive elements, but not necessarily abutting them, wherein said isolation spans the semiconductor layer;
at least a scintillator element which converts x-ray radiation into light, upon the semiconductor substrate; and,
at least one electrical amplification element which electrically contacts at least one of said multiple photo-sensitive elements.
